(19) United States
(12) Patent Application Publication
(10) Pub. No.: US 2013/0106868 A1
(43) Pub. Date: May 2, 2013

(54) ENCAPSULATION OF EMS DEVICES ON GLASS

(71) Applicant: Ravindra V. Shenoy, Dublin, CA (US)

(72) Inventor: Ravindra V. Shenoy, Dublin, CA (US)

(73) Assignee: QUALCOMM MEMS TECHNOLOGIES, INC., San Diego, CA (US)

(21) Appl. No.: 13/286,124

(22) Filed: Oct. 31, 2011

(51) Int. Cl. G06T 1/00; C23C 14/34; H01L 23/28; B44C 1/17; B23K 31/02; B29C 63/00; B44C 1/175

(52) U.S. Cl. 345/501; 156/703; 427/154; 204/192.1; 156/150; 156/234; 228/176; 174/521

(57) ABSTRACT

This disclosure provides systems, methods and apparatus for fabricating encapsulated devices, including electromechanical systems devices. In one aspect, a cover plate including one or more encapsulation lids releasably attached to a carrier substrate is provided. The one or more encapsulation lids can be joined to a device substrate to encapsulate one or more devices on the device substrate in a batch process. After joining, the encapsulation lids are released from the carrier substrate resulting in the formation of encapsulated devices on the device substrate. In another aspect, encapsulated devices are provided.

### TECHNICAL FIELD

This disclosure relates to structures and processes for encapsulating electromechanical systems devices on substrates.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography and/or other micromachining processes that etch away parts of substrates and/or deposited material layers, or that add layers to form electrical and electromechanical devices.

One type of EMS device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

EMS packaging protects the functional units of the system from the environment, provides mechanical support for the system components, and provides an interface for electrical interconnections.

### SUMMARY

The systems, methods and devices of the disclosure each have several innovative aspects, no single one of which is solely responsible for the desirable attributes disclosed herein.

One innovative aspect of the subject matter described in this disclosure includes methods of encapsulating devices, such as electromechanical systems (EMS) devices. In some implementations, a method includes providing a cover plate including a plurality of encapsulation lids attached to a carrier substrate, aligning the plurality of encapsulation lids with a plurality of devices on a device substrate, joining the plurality of encapsulation lids to the device substrate and releasing the joined encapsulation lids from the carrier substrate. Methods of releasing the joined encapsulation lids can include exposing a removable layer to one or more of a chemical etchant and electromagnetic radiation.

In some implementations, a method includes forming a removable layer on a carrier substrate and forming a plurality of encapsulation lids attached to the carrier substrate by the removable layer. In some implementations, a method includes forming a plurality of recesses in a carrier substrate, conformally coating the carrier substrate including the recesses with a removable layer and forming encapsulation lids in the coated recesses. In some implementations, a method includes coating a planar carrier substrate with a removable layer and forming encapsulation lids on the removable layer. Methods of forming the removable layer can include one or more of sputter deposition, electroless plating and evaporation. In some implementations, forming a plurality of encapsulation lids can include plating a metal such as nickel (Ni) or a Ni alloy. Examples of removable layers include thin metal films and laser-cleavable polymers.

Another innovative aspect of the subject matter described in this disclosure can be implemented in an apparatus including a substrate and a device, such as an EMS device, disposed on the substrate. The device can have a thickness of at least 3 microns and can be covered by an encapsulation lid joined to the substrate. One or more exposed contact pads can be disposed on the substrate outside of the encapsulation lid and electrically connected to the device. In some implementations, the apparatus can include a plurality of devices disposed on the substrate, each of which can be individually covered by one of a plurality of encapsulation lids joined to the substrate. In some implementations, the encapsulation lid(s) include Ni or a Ni alloy. In some implementations, the encapsulation lid(s) can be infrared transparent. The device substrate can be, for example, a glass substrate.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects and advantages will become apparent from the description, the drawings and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a schematic illustration of a device substrate and a cover plate prior to encapsulation.

FIG. 10 shows an example of a flow diagram illustrating a process for encapsulating MEMS devices.

FIGS. 11A-11E show examples of cross-sectional schematic illustrations of various stages of in a method of encapsulating a MEMS device.

FIG. 12 shows an example of a flow diagram illustrating a process for fabricating individual dies using a batch level encapsulation process.

FIGS. 13A-13E show examples of schematic illustrations of various stages of a batch level process of fabricating individual dies including encapsulated devices.

FIG. 14 shows an example of a cross-sectional schematic illustration of an implementation of a device substrate.

FIGS. 15 and 16 show examples of flow diagrams illustrating a process for forming a cover plate.

FIGS. 17A-17E show examples of cross-sectional schematic illustrations of various stages in a method of forming a cover plate.

FIG. 18 shows an example of a flow diagram illustrating a process for forming a cover plate.

FIGS. 19A-19F show examples of cross-sectional schematic illustrations of various stages in a method of forming a cover plate.

FIG. 20 shows an example of a flow diagram illustrating a process for forming a cover plate including encapsulation lids for bolometers.

FIGS. 21A-21F show examples of cross-sectional schematic illustrations of various stages in a method of forming a cover plate including encapsulation lids for bolometers.

FIG. 22 shows an example of a cross-sectional illustration of a portion of a cover plate including an encapsulation lid with structural support posts.

FIGS. 23A-23C and 24A-24C show examples of cross-sectional schematic illustrations of alignment and joining of encapsulation lids and release of a carrier substrate.

FIG. 25 shows an example of a flow diagram illustrating a packaging process for a die including an encapsulated MEMS device.

FIG. 26 shows an example of a cross-sectional schematic illustration of a die including an encapsulated MEMS device and an application-specific integrated circuit (ASIC) on a printed circuit board (PCB).

FIG. 27 shows another example of a flow diagram illustrating a packaging process for a die including an encapsulated MEMS device.

FIGS. 28A-28C shows examples of a cross-sectional schematic illustration of a flip-chip die including an encapsulated MEMS device and an ASIC on a PCB.

FIGS. 29A and 29B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to packaging of electromechanical systems (EMS) devices including MEMS devices. Packages to encapsulate such devices and related fabricated methods are described herein. While implementations of the methods of encapsulation and the resulting encapsulated devices are described chiefly in the context of packaging of MEMS devices and other EMS devices, the methods and packages are not so limited and may be implemented for packaging of other types of devices or structures, such as nano- or macro devices.

In some implementations, methods of encapsulating EMS devices are described. Encapsulation of EMS devices can provide a controlled atmosphere for operation of the devices. In some implementations, the methods are batch encapsulation processes performed prior to die singulation. Batch level encapsulation of MEMS devices refers to encapsulating a plurality of MEMS devices simultaneously and can be performed at a panel, wafer, substrate, sub-panel, sub-wafer or sub-substrate level. Certain operations in a batch level encapsulation process are performed once for a plurality of devices, rather than performed separately for each device. In some implementations, the batch level process involve encapsulating a plurality of devices that have been fabricated on a wafer, panel or other substrate prior to singulation of the wafer, panel or other substrate into individual dies.

In some implementations, devices are encapsulated on a substrate, such as a glass, plastic or silicon substrate. A package including the substrate and encapsulated device(s) can have a thickness of about of 5-100 microns beyond the thickness of the substrate. For example, a package for a MEMS device fabricated on a 500 micron substrate may be about 505-600 microns. In some implementations, a package can have a thickness of about 10-50 microns beyond the thickness of the substrate. The encapsulation methods described herein can be used to encapsulate a variety of devices having various thicknesses and surface areas. For example, in some implementations, devices having thicknesses of about 1-50 microns or greater can be encapsulated. Also, in some implementations, devices having areas of about 1 square micron to tens of square millimeters can be encapsulated.

In some implementations, the batch level methods involve providing a cover plate and a device substrate, the device substrate including a plurality of devices and the cover plate including a plurality of encapsulation lids configured to encapsulate at least some of the plurality of devices. The cover plate can include a carrier substrate to which the encapsulation lids are attached. The encapsulation lids can be joined to the device substrate to encapsulate the plurality of devices, and then released from the carrier substrate.

Particular implementations of the subject matter described in this disclosure can be implemented to realize one or more of the following potential advantages. In some implementations, batch panel-level processing methods can be used to eliminate or reduce die-level processing. Advantages of encapsulation and packaging in a batch process at a panel, or a sub-panel, level include a large number of units fabricated in parallel in the batch process, thus reducing costs per unit as compared to individual die level processing. The use of batch processes such as lithography, etching and plating over a large substrate in some implementations allows tighter tolerances and reduces die-to-die variation. In some implementations, the encapsulation methods can be used to fabricate thin packaged devices.

In some implementations, the methods described herein can be used to encapsulate EMS structures having a wide range of sizes. Advantages include fabricating very thin packaged devices as well as encapsulating EMS structures that are tens of microns tall and that cannot be encapsulated by thin film encapsulation methods. Also in some implementations, the encapsulated environment in which a device is disposed can be tailored. Advantages include the flexibility of providing a hermetic or non-hermetic environment and providing a dialed-in pressure and gas composition for the encapsulated device. In some implementations, an encapsulation material and/or encapsulation processing that is incompatible with EMS fabrication can be used. Advantages include increased design choices for encapsulation materials and processing.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

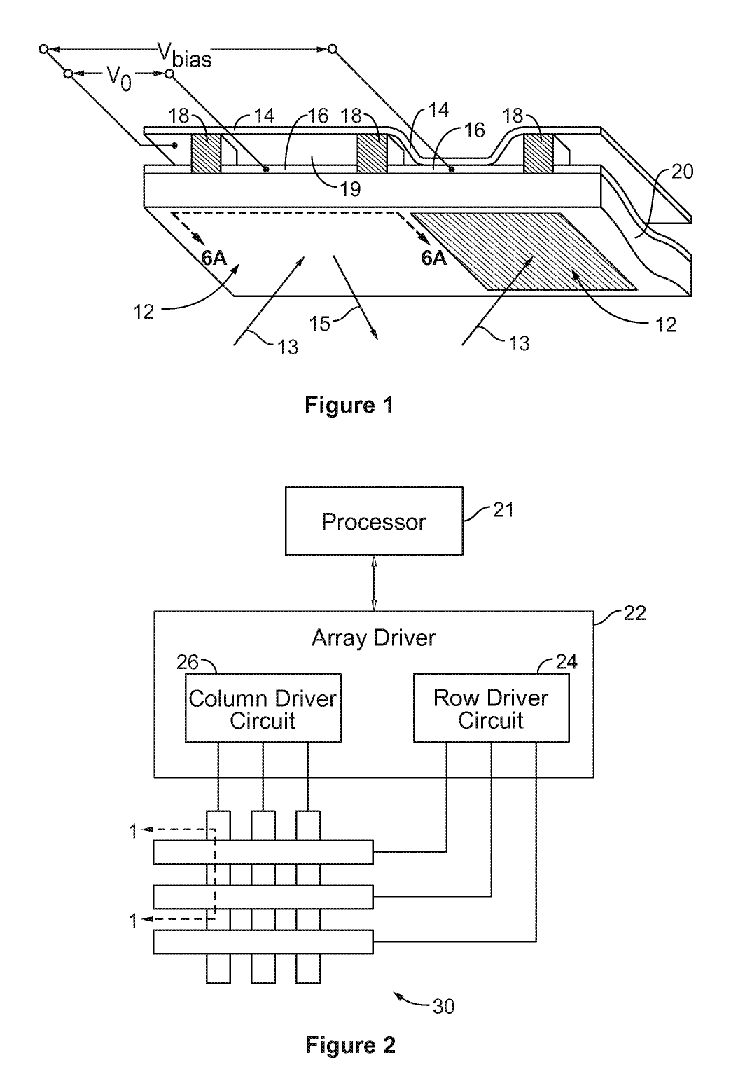

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (e.g., of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

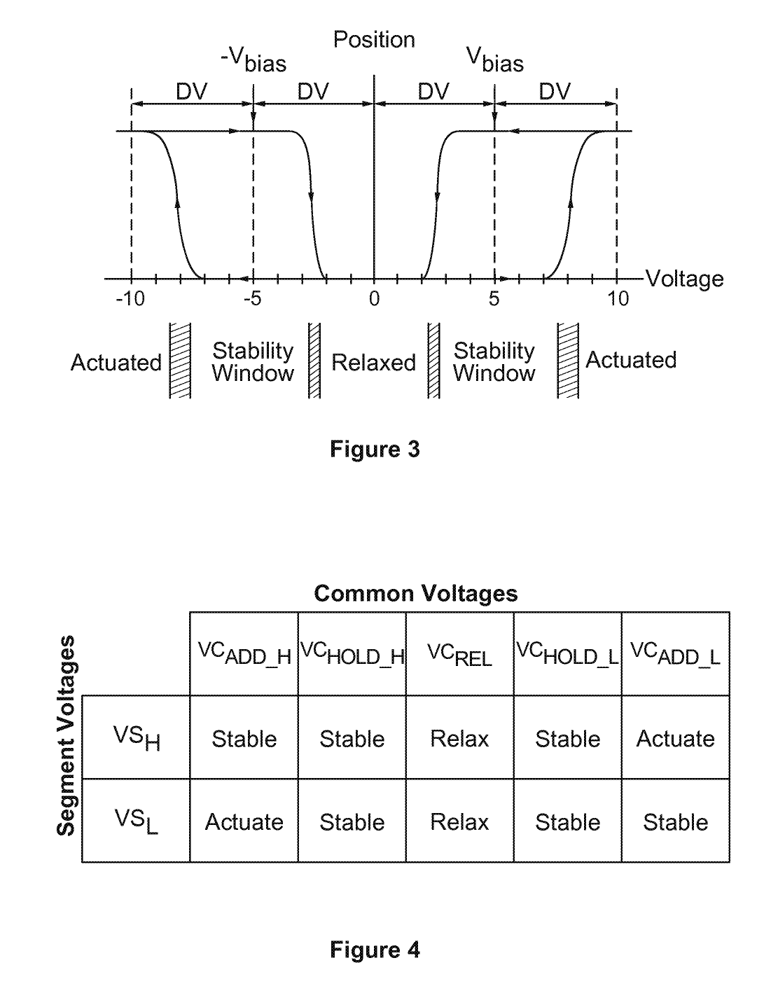

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

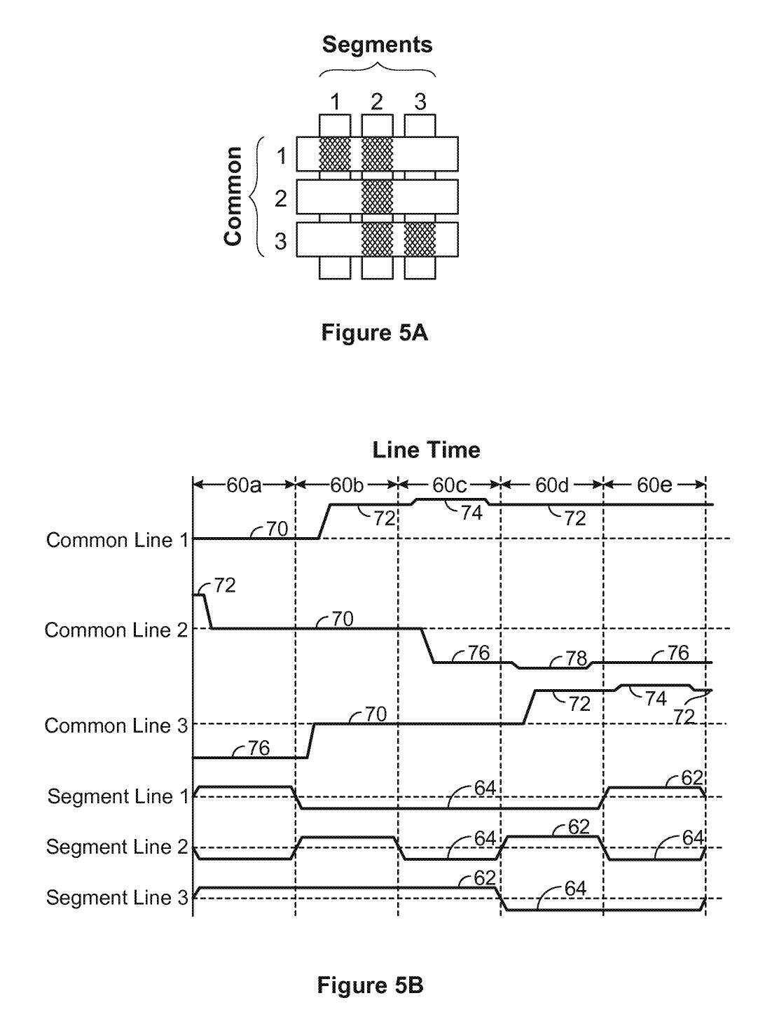

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

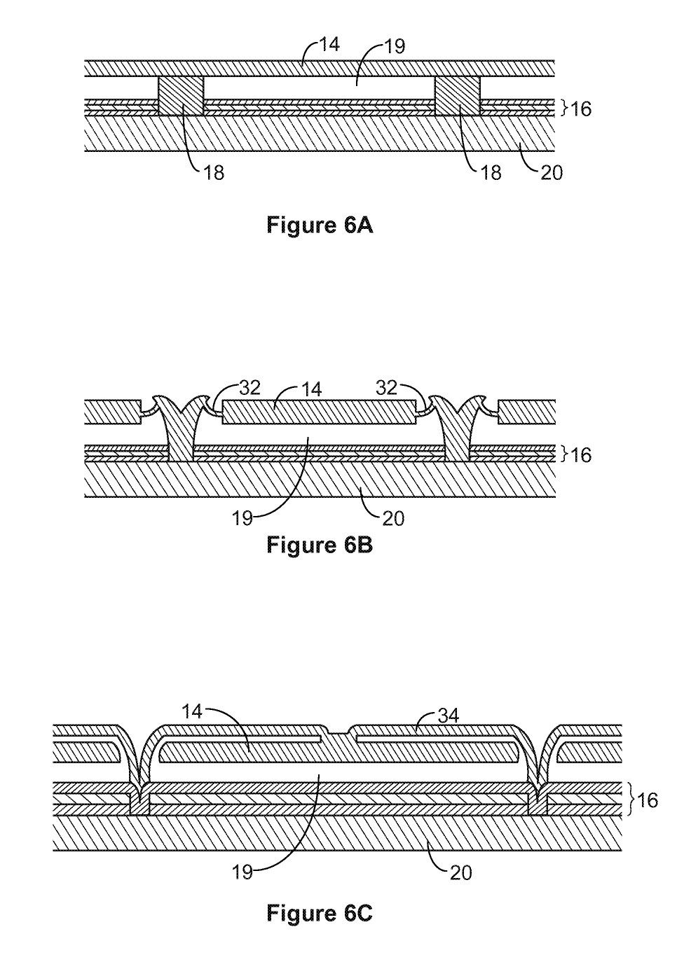

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

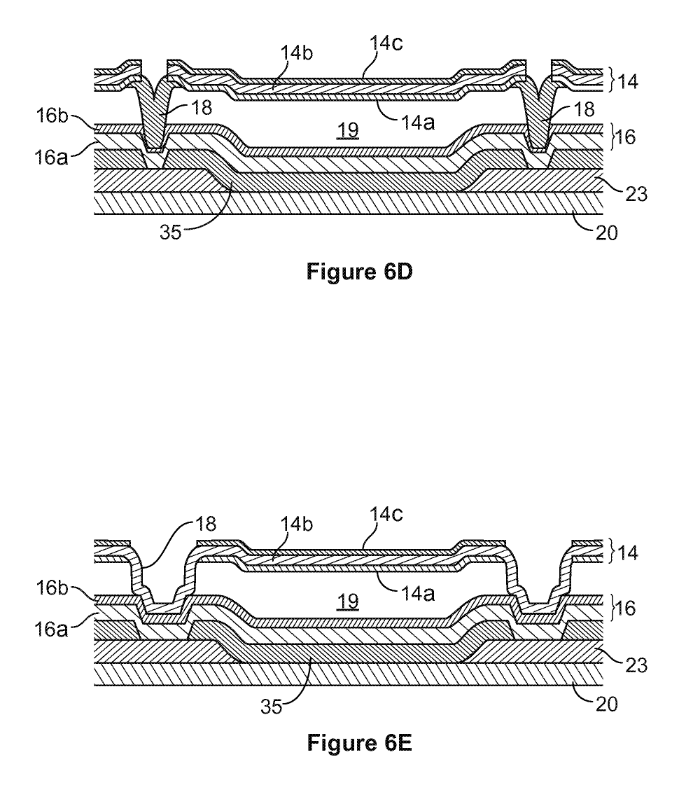

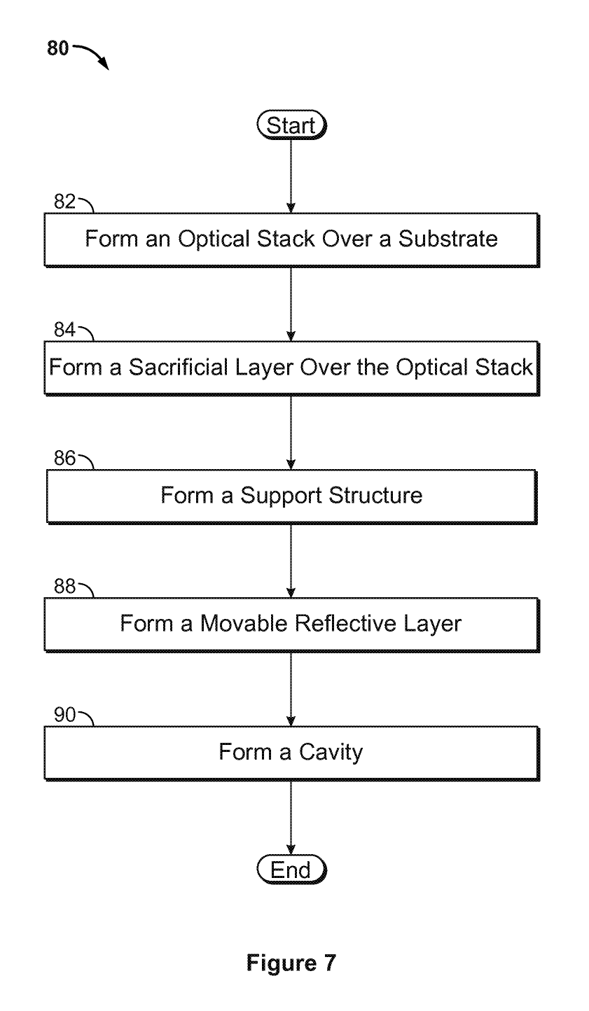

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

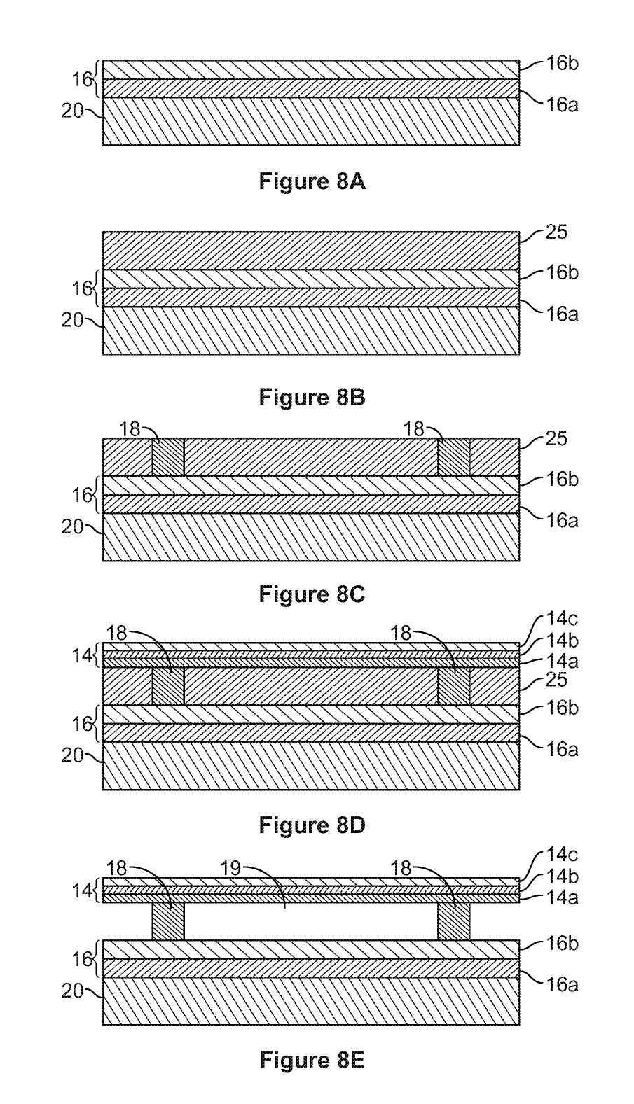

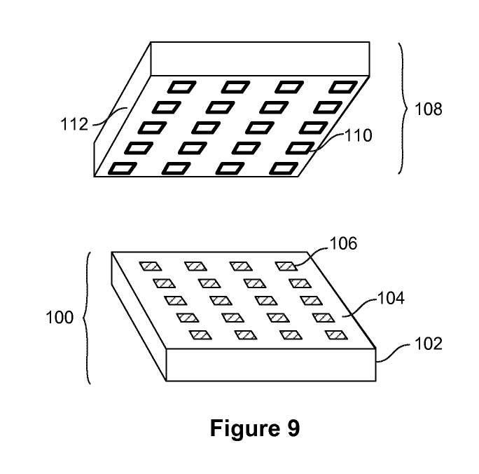

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer and an aluminum alloy that serves as a reflector and a bussing layer, with a thickness in the range of about 30-80 Å, 500-1000 Å and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In some implementations, the optical absorber 16a is an order of magnitude (ten times or more) thinner than the movable reflective layer 14. In some implementations, the optical absorber 16a is thinner than the reflective sub-layer 14a.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

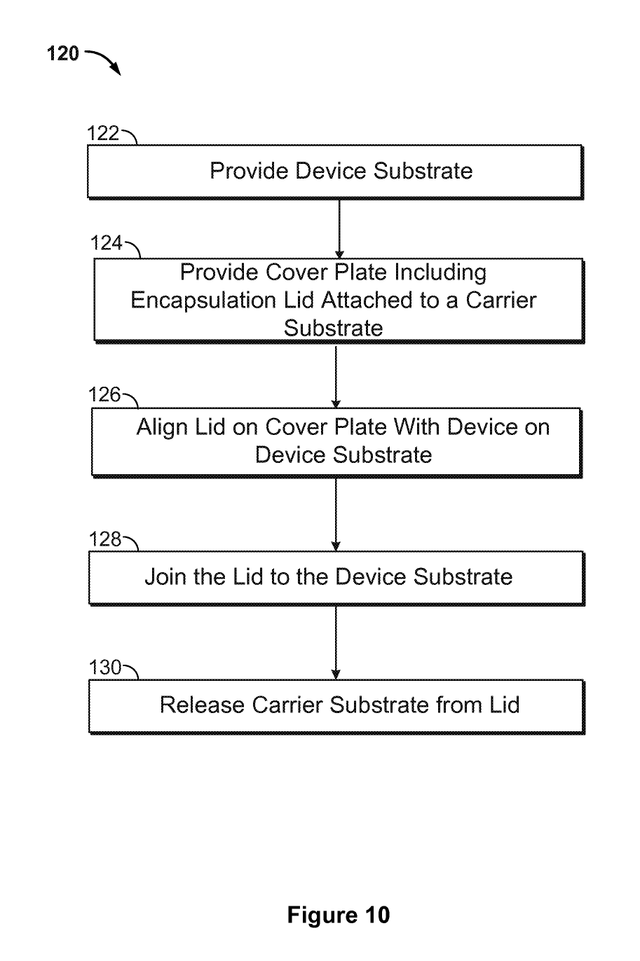

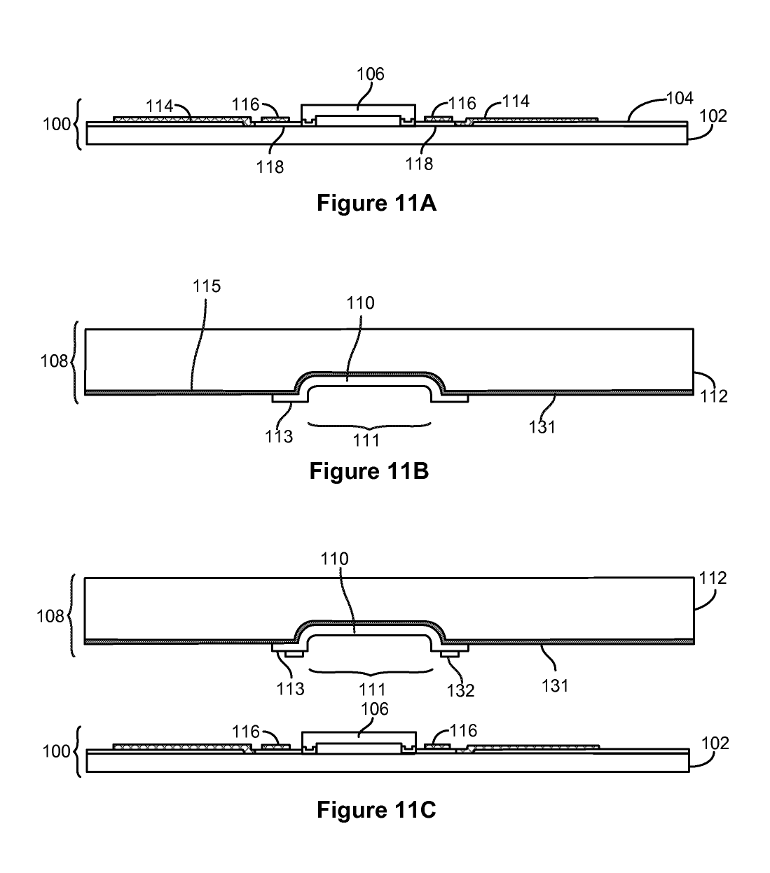

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems (EMS) device such as interferometric modulators of the general type illustrated in FIGS. 1 and 6. The manufacture of an EMS device also can include other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although the sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD) or spin-coating.

The process 80 continues at block 86 with the formation of a support structure such as post 18, illustrated in FIGS. 1, 6 and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps including, for example, reflective layer (such as aluminum, aluminum alloy, or other reflective layer) deposition, along with one or more patterning, masking and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Implementations described herein relate to glass packaging of various kinds of devices including electrical, optical and electromechanical systems devices (for example IMODs and other EMS, MEMS or NEMS devices). In some implementations, methods of encapsulating EMS devices are described. Encapsulation of devices can provide a controlled atmosphere for operation of the devices. In some implementations, the methods are batch level (such as wafer, panel or sub-panel) encapsulation processes performed prior to die singulation. While implementations of the methods of encapsulation and the resulting packaged devices are described below chiefly in the context of packaging of MEMS devices, the methods and packages are not so limited and may be applied in other contexts in which a package of is employed, for example in packaging of NEMS or other EMS devices, integrated circuit (IC) devices or other devices.

Batch level encapsulation of MEMS devices refers to encapsulating a plurality of MEMS devices simultaneously. In some implementations, certain operations in a batch level encapsulation process are performed once for the plurality of MEMS devices, rather than performed separately for each device. In some implementations, the batch level process involves encapsulating a plurality of devices that have been fabricated on a wafer, panel or other substrate prior to singulation of the wafer, panel or other substrate into individual dies.

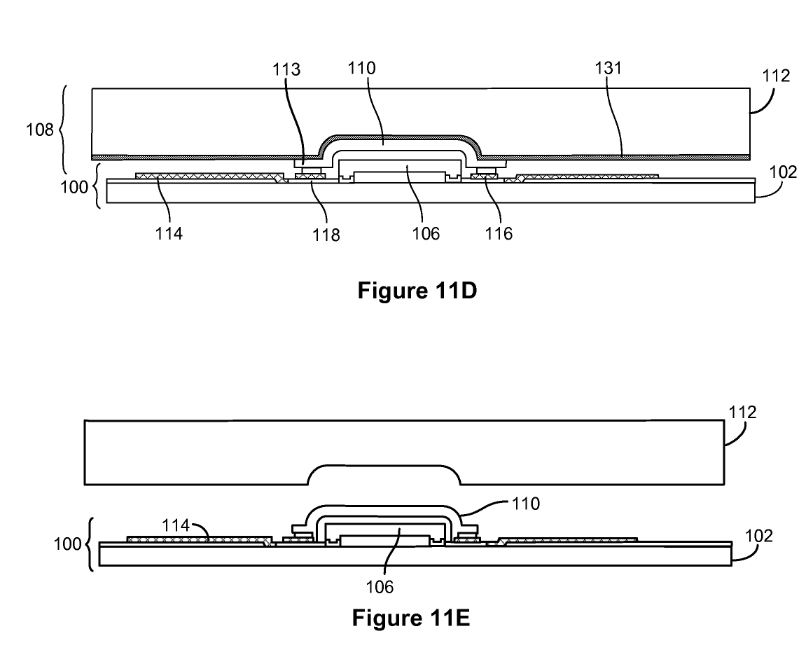

In some implementations, the batch level methods involve providing a cover plate and a device substrate. The device substrate includes a plurality of devices and the cover plate includes a plurality of encapsulation lids configured to encapsulate at least some of the plurality of devices. FIG. 9 shows an example of a schematic illustration of a device substrate and a cover plate prior to encapsulation. Device substrate 100 includes MEMS devices 106 arrayed on a top surface 104 of a substrate 102. In some implementations, the substrate 102 is a glass substrate. In some implementations, each of the MEMS devices 106 is configured for eventual singulation into a die. Examples of MEMS devices 106 include IMODs, gyroscopes, accelerometers, pressure sensors, infrared sensors, other sensors, timing devices, resonators, tunable capacitors, microphones, microspeakers and the like. In addition to MEMS devices, any number of other components such as pads, traces, interconnects, internal metallization, through-glass vias and the like may be present on any surface of or through the device substrate 100. Any number of MEMS devices 106 may be arrayed or otherwise arranged on the top surface 104 of substrate 102. For example, tens, hundreds, thousands or more MEMS devices may be fabricated on a single substrate. The devices and associated components may all be the same or may differ across the substrate according to the desired implementation. The height of MEMS devices 106 may be, for example, between about 1 micron and 100 microns. For example, a thin-film fabricated MEMS device may have a height of between about 1 micron and 10 microns, and a plated MEMS device may have a height between about 10 microns and 30 microns. In some implementations, a MEMS device is at least about 3 microns tall.

Substrate 102 may be of any appropriate area and thickness. For example, in some implementations, a device substrate such as a glass plate or panel having an area on the order of four square meters or greater is provided with a thickness, for example, of 0.3, 0.5 or 0.7 millimeters. Alternatively, round substrates with diameters of 100 millimeters, 150 millimeters or other diameters may be provided. In some other implementations, square or rectangular sub-panels cut from a larger panel of glass or other substrate material may be provided. The substrate thickness may be between about 50 and 700 microns, such as about 100 microns, 300 microns or 500 microns. For example, in some implementations in which the MEMS device 106 is configured to mount onto a printed circuit board (PCB) after singulation, the substrate may have thicknesses of at least about 300 microns, for example, between about 300 and 500 microns, although larger substrate thicknesses are also possible.

The substrate 102 may be transparent, such as transparent substrate 20 described above with respect to FIGS. 6A-6E and 8A-8E, or may be non-transparent. The substrate 102 may be or include, for example, a borosilicate glass, a soda lime glass, quartz, Pyrex or other suitable glass material. In some other implementations, the device substrate may be a non-glass material. For example, a device substrate can be a plastic, Si, ceramic or other insulating non-glass material. In some examples, a device substrate can be a silicon substrate that includes through-silicon vias or a ceramic substrate having internal metallization. The description that follows will focus on implementations with a glass substrate, but it is understood that other substrates, such as non-glass insulating, semiconducting or conducting substrates, also may be used. In implementations where a joining or other process includes heating and subsequently cooling the substrates, it can be useful for both the device substrate and the carrier substrate to have similar or close coefficients of thermal expansion.

The cover plate 108 includes a plurality of encapsulation lids 110 attached to a carrier substrate 112. As discussed further below, in some implementations, encapsulation lids 110 are releasably attached to a carrier substrate 112. The cover plate 108 may further include a removable layer (not shown in FIG. 9) attaching or bonding the encapsulation lids 110 to the carrier substrate 112. Each encapsulation lid 110 can be configured to encapsulate one of the MEMS devices 106. The carrier substrate 112 may be of any appropriate area and thickness. For example, in some implementations, a carrier substrate such as a glass plate or panel having an area on the order of four square meters or greater is provided with a thickness, for example, of 0.3, 0.5 or 0.7 millimeters. Alternatively, round substrates with diameters of 100 millimeters, 150 millimeters or other diameters may be provided. In some other implementations, square or rectangular sub-panels cut from a larger panel of glass or other substrate material may be provided. In some implementations, carrier substrate 112 is approximately the same area and shape as the substrate 102 of the device substrate 100. In the example depicted in FIG. 9, cover plate 108 includes one encapsulation lid 110 for each MEMS device 106. In some other implementations, the area of the cover plate may be smaller than that of the device substrate, having fewer lids than the number of devices on the device substrate. In these implementations, multiple cover plates can be used to encapsulate the MEMS devices 106 formed on the device substrate 100, or a single cover plate can be used in successive operations to encapsulate all of the MEMS devices if desired.

The carrier substrate 112 may be a transparent or non-transparent substrate. Example materials include a borosilicate glass, a soda lime glass, quartz, Pyrex or other suitable glass material. In some implementations, the carrier substrate is a non-glass material such as plastic, Si or ceramic. Examples of ceramic substrates include aluminum oxide (Al₂O₃) or aluminum nitride (AlN). In some implementations, the carrier substrate material is chosen to have a coefficient of thermal expansion (CTE) that is matched to that of the device substrate 100. For example, in some implementations, the device substrate 100 and the carrier substrate 112 are both glass or both plastic to avoid CTE mismatch.

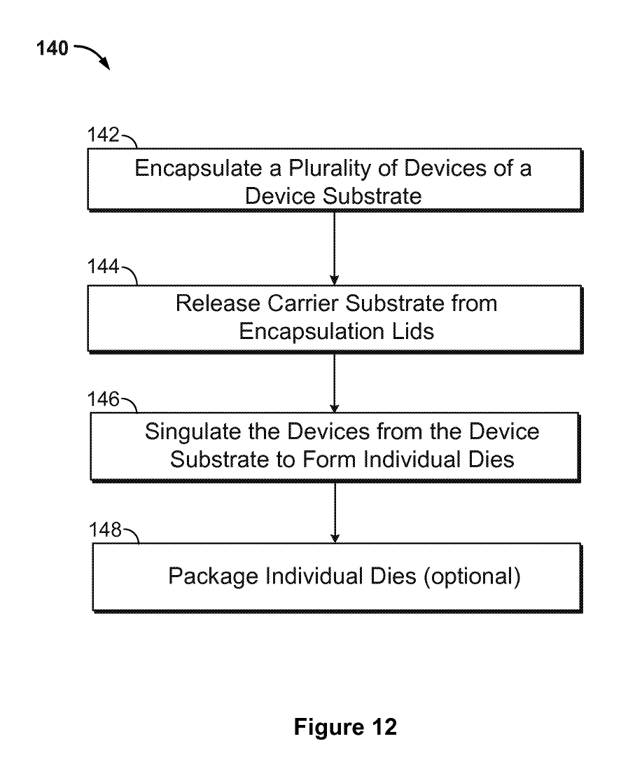

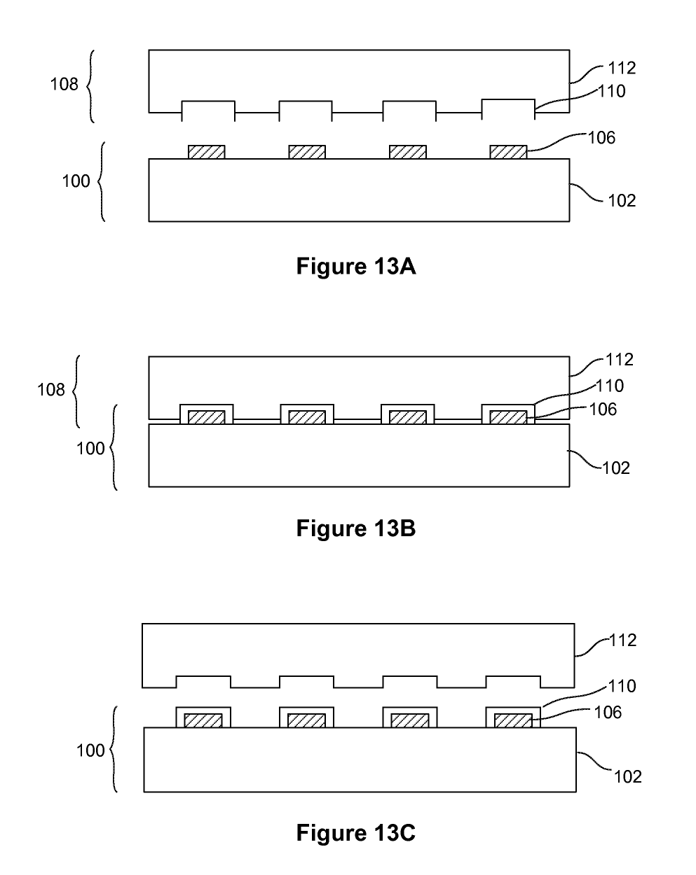

FIG. 10 shows an example of a flow diagram illustrating a process for encapsulating MEMS devices. FIGS. 11A-11E show examples of cross-sectional schematic illustrations of various stages of in a method of encapsulating a MEMS device.

In FIG. 10, process 120 begins at block 122 by providing a device substrate. A device substrate is a substrate that has one or more devices disposed thereon. Examples of device substrates are described above with respect to FIG. 9. In some implementations, the devices are or include one or more MEMS devices previously fabricated on, attached to or placed on the device substrate. In some implementations, the substrate is substantially planar having substantially parallel major surfaces (also referred to as top and bottom surfaces). Each surface may include various recessed or raised features. For example, a surface may include recesses to accommodate devices or components thereof.

FIG. 11A is an example of a cross-sectional illustration of a portion of a device substrate. (It should be noted that the geometry is not shown to scale with the illustration expanded the z-direction to show details.) The depicted portion includes one repeating unit of a device substrate 100, including MEMS device 106 and associated components on a top surface 104 of a substrate 102. In some implementations the entire device substrate (not shown) includes a plurality of such devices arrayed on the top surface 104. In the example depicted in FIG. 11A, the associated components include bond pads 114 and metal feed-throughs 118. Bond pads 114 are metalized areas to which connections can be made by techniques such as wire bonding, soldering or flip-chip attachment and can be configured for connection to external components such as printed circuit boards (PCBs), application-specific integrated circuits (ASICs) and the like. Metal feed-throughs 118 provide electrical connection from MEMS device 106 to bond pads 114. The presence, number and arrangement of components such as bond pads, metal feed-throughs, metal traces, through-glass vias (not shown) and the like may vary according to the desired implementation. A joining ring 116 surrounds the MEMS device 106. As described further below with reference to FIG. 11D, the joining ring 116 provides a point of attachment for an encapsulating lid. In implementations where the joining ring 116 includes a conducting material such as a metal, the metal feed-throughs 118 can include a thin insulating layer so that signals conducted along metal feed-throughs 118 are electrically isolated from the joining ring 116.

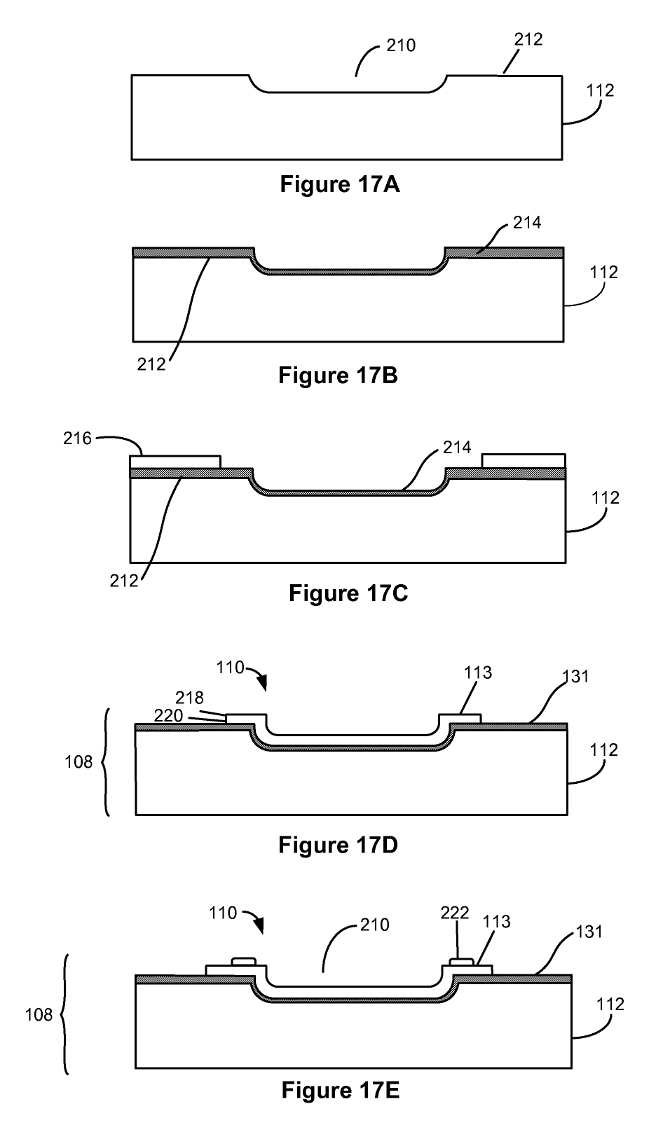

Returning to FIG. 10, the process 120 continues at block 124 with providing a cover plate including encapsulation lid(s) releasably attached to a carrier substrate. Methods of attaching lids to a carrier substrate are discussed further below with respect to FIGS. 15-22. FIG. 11B is an example of a cross-sectional illustration of a portion of a cover plate 108. The depicted portion includes one repeating unit of a cover plate 108 including an encapsulation lid 110 attached to carrier substrate 112. In some implementations, the entire cover plate 108 includes a plurality of such encapsulation lids 110 arrayed or otherwise appropriately arranged such that they can be aligned with a plurality of devices on a device substrate. As depicted in FIG. 11B, the cover plate 108 includes a removable layer 131. The removable layer 131 is disposed on the carrier substrate 112 and can separate the encapsulation lid 110 from the cover plate 108. The removable layer 131 can be a material that is removable from the encapsulation lid 110 and/or the carrier substrate 112 upon exposure to chemical etchants, electromagnetic radiation, heat, or other removal mechanism.

In the example depicted in FIG. 11B, encapsulation lid 110 includes a portion 111 recessed from a surface 115 of carrier substrate 112 and a flange 113 extending around portion 111.

The process 120 continues at block 126 with aligning the encapsulation lids on the cover plate with the devices on the device substrate. FIG. 11C is a cross-sectional illustration of alignment of the encapsulation lid 110 of the cover plate 108 with the MEMS device 106 of the device substrate 100. The cover plate 108 is positioned over the device substrate 100 such that flange 113 of encapsulation lid 110 is aligned with joining ring 116 of device substrate 100, and recessed portion 111 of encapsulation lid 110 is aligned with MEMS device 106. In the depicted example, solder material 132 can be disposed on the flange 113 for joining to the joining ring 116 in a subsequent operation.

The process 120 continues at block 128 with joining the lids to the device substrate. FIG. 11D is a cross-sectional illustration of encapsulation lid 110 joined to device substrate 100. In the depicted example, encapsulation lid 110 is joined to joining ring 116 by solder reflow; other joining techniques are described further below. At this stage (for example, after block 128) encapsulation lid 110 encapsulates MEMS device 106, and device substrate 100 includes encapsulation lid 110. In some implementations, encapsulation lid 110, along with substrate 102, isolates MEMS device 106 from the ambient environment. In alternative implementations, one or more access ports (not shown) in encapsulation lid 110 and/or substrate 102 provide access to MEMS device 106. Metal feed-throughs 118 feed under joining ring 116 and provide an electrical connection to MEMS device 106. A plurality or all devices on a device substrate can be simultaneously encapsulated in a joining operation.

The process 120 continues at block 130 with release of the encapsulation lids, now joined to the device substrate, from the carrier substrate. As indicated above, in some implementations, this involves selectively etching or otherwise removing a removable layer that attaches the encapsulation lids to the carrier substrate. FIG. 11E is a cross-sectional illustration of release of carrier substrate 112 from encapsulation lid 110. Removable layer 131, depicted in FIGS. 11B-11D, is no longer present, having been etched. Carrier substrate 112 can be attached to another set of encapsulation lids or discarded according to the desired implementation. Device substrate 100, including encapsulated MEMS device 106, is ready for further processing operations.

As indicated above, in some implementations an encapsulation process as described with reference to FIGS. 10 and 11A-11E is a batch level process in which all or at least a plurality of devices on a device substrate are encapsulated as a batch. In some other implementations, the encapsulation process can be performed to encapsulate individual devices in a non-batch process.

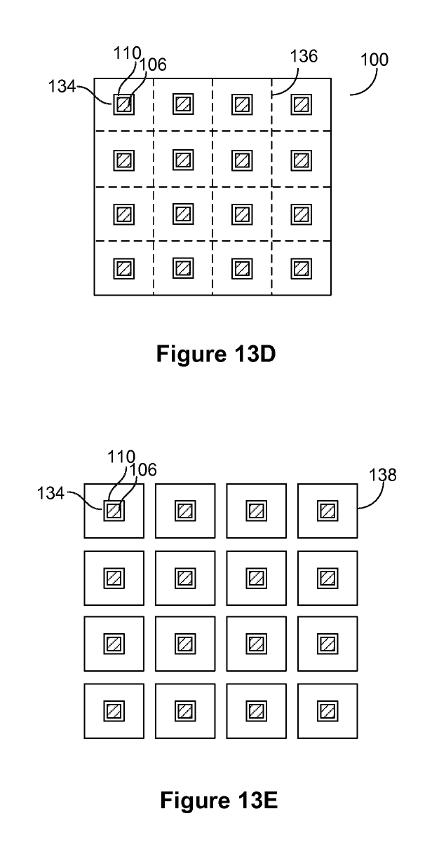

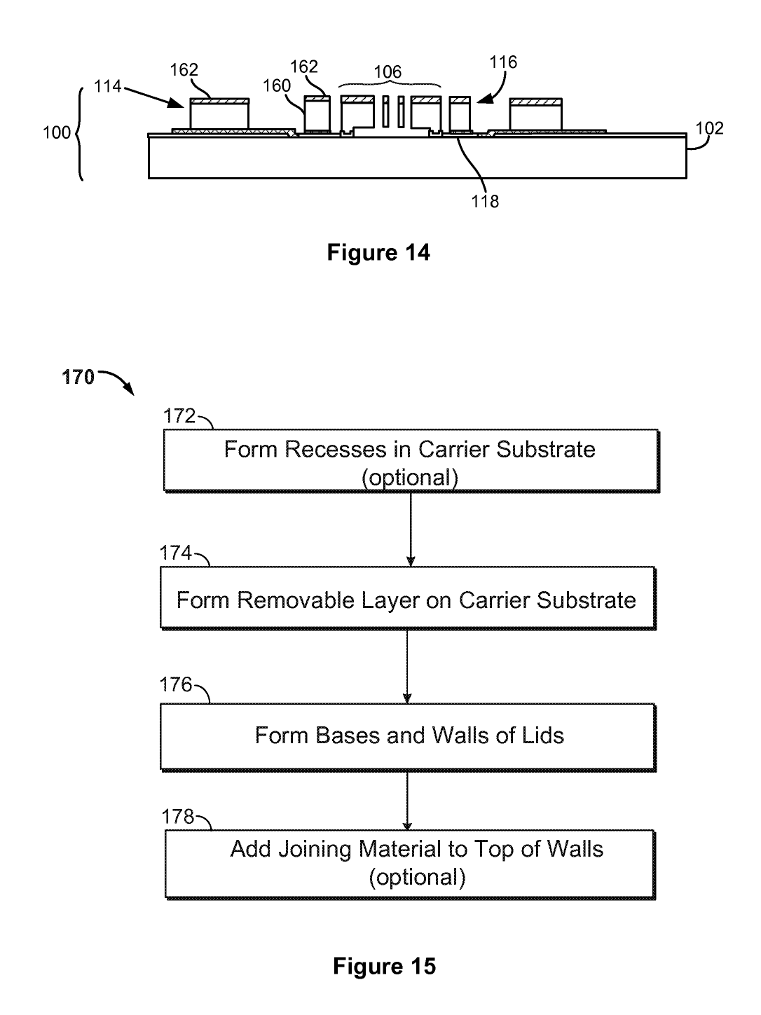

FIG. 12 shows an example of a flow diagram illustrating a process for fabricating individual dies using a batch level encapsulation process. FIGS. 13A-13E show examples of schematic illustrations of various stages of a batch level process of fabricating individual dies including encapsulated devices. In FIG. 12, process 140 begins at block 142 with the encapsulation of a plurality of devices of a device substrate. Encapsulating a device of a device substrate is discussed above with reference to FIGS. 10 and 11A-11E. FIGS. 13A and 13B are cross-sectional schematic illustrations of operations of encapsulating devices 106 of a device substrate 100 with encapsulation lids 110. FIG. 13A is a cross-sectional illustration of device substrate 100, including substrate 102 and devices 106, and cover plate 108, including carrier substrate 112 and encapsulation lids 110, prior to encapsulation. FIG. 13B is a cross-sectional schematic depiction of encapsulations lids 110 joined to device substrate 100 and encapsulating devices 106. The process 140 continues at block 144 by releasing a carrier substrate from the plurality of encapsulation lids 110. Releasing a carrier substrate is discussed above with reference to block 130 of FIG. 10, and further below. FIG. 13C is a cross-sectional depiction of devices 106 each encapsulated by a separate encapsulation lid 110. The process 140 continues at block 146 by singulating the devices from the device substrate to form individual dies, each die including an encapsulated device. FIG. 13D is a plan schematic depiction of a device substrate 100 prior to singulation. Device substrate 100 includes encapsulated arrayed devices 134, including device 106 and encapsulation lid 110. Dicing lines 136 indicate the desired cut locations. FIG. 13E is a plan schematic depiction of singulated individual dies 138, each die including an encapsulated device 134.

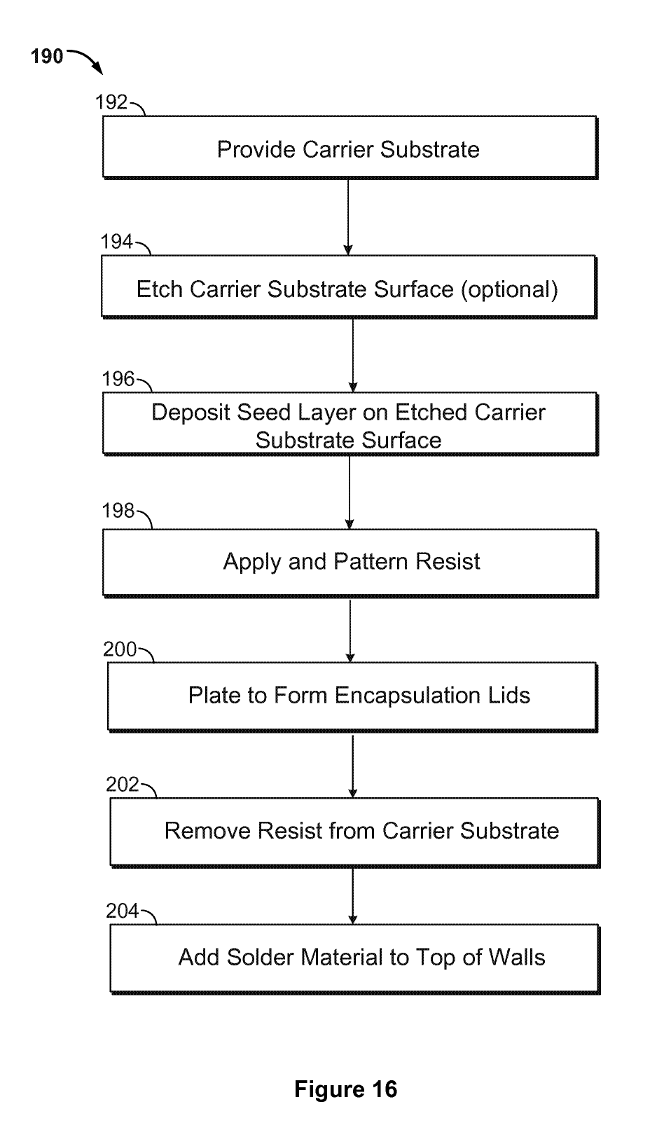

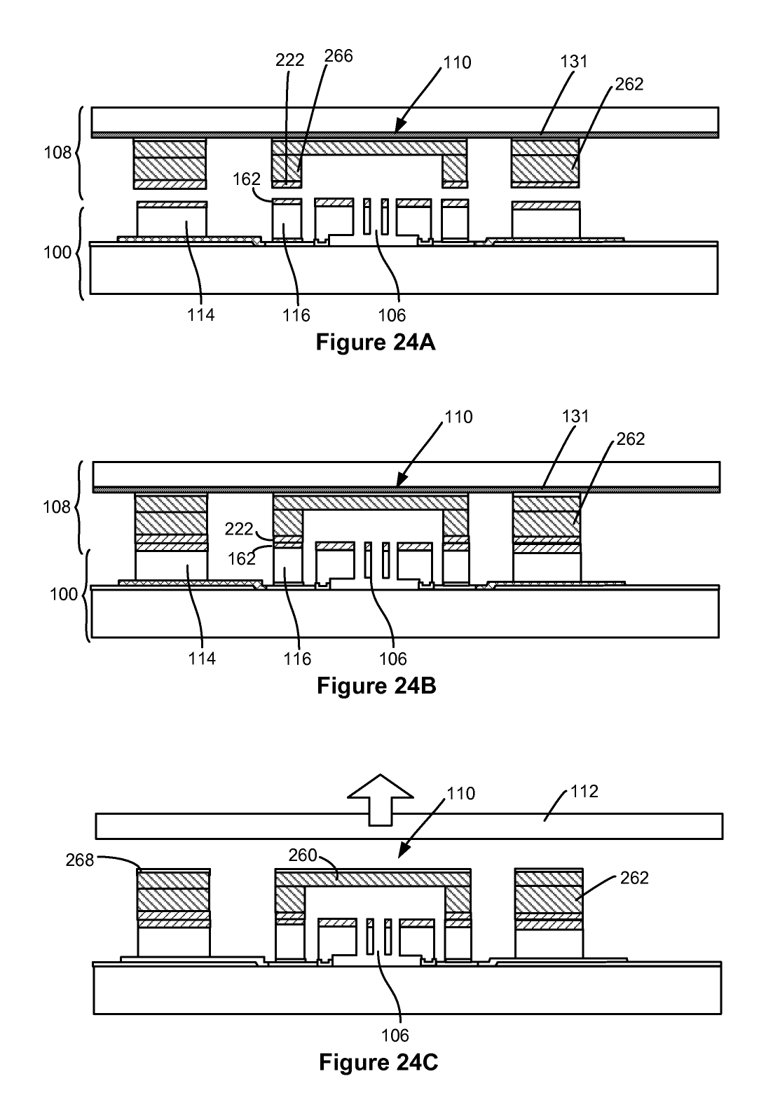

Returning to FIG. 12, the process 140 can continue in block 148 with packaging the individual dies. Packaging individual dies is discussed further below with reference to FIG. 25-28C. Further description of implementations of operations described above with reference to FIGS. 10-13E is given below with reference to FIGS. 14-28C.

As indicated above, some implementations include providing a device substrate. The device substrate includes one or more devices disposed on a substrate and can include associated components such as bond pads, metal traces and the like. One example of a device substrate is described above with reference to FIG. 11A. In some implementations, the device substrate includes a joining ring 116 surrounding a MEMS device 106, and at which an encapsulation lid 110 can be joined to the substrate 102. The material or materials that form the joining ring 116 can vary according to method of joining and the desired implementation. For example, in some implementations, the joining ring 116 can include a solderable metallurgy. Examples of solderable metallurgies include nickel/gold (Ni/Au), nickel/palladium (Ni/Pd), nickel/palladium, gold (Ni/Pd/Au), copper (Cu), gold (Au), copper/nickel/gold (Cu/Ni/Au), copper/nickel-cobalt/gold (Cu/NiCo/Au) and copper/nickel/palladium/gold (Cu/Ni/Pd/Au). As discussed below with reference to FIG. 15, in some implementations the joining ring 116 has a different metallization than that of a removable layer on the cover plate. For example, if a Cu-based removable layer is employed, the joining ring is typically not Cu-based. This is to preserve etch selectivity of the removable layer with respect to the joining ring 116. In some implementations, the joining ring 116 includes an epoxy or polymer adhesive material in addition or instead of a metal.

The joining ring 116 may be shaped in any appropriate manner and is generally shaped and sized to correspond to the encapsulation lid 110 to which it is configured to be joined. Example shapes include circles, ovals, squares, rectangles, etc. In some implementations, a joining ring 116 is formed such that it completely surrounds a device, such as MEMS device 106. The joining ring 116 can be unbroken or can include breaks.

The width of the joining ring 116 is sufficient to provide an adequate seal and can vary according to method of joining and the desired implementation. The seal can be hermetic or non-hermetic according to the desired implementation. In some implementations, the width is between about 50-200 microns. In some implementations in which solder or eutectic joining is performed, a width of about 50-100 microns is sufficient to provide an adequate seal. In some implementations, the width can vary depending on the method by which joining ring solder material is formed. For seals having widths of about 200 microns or greater, screen printing can be used. For seals less than about 200 microns wide, plating can be used. In some implementations in which an epoxy or polymer adhesive is used, the width of the joining area can be larger, for example, around 500 microns, to provide a hermetic seal. In some implementations, the target width of a joining ring 116 or joining area is increased to accommodate CTE mismatch between a device substrate and a carrier substrate during the joining process.

In some implementations, device substrate 100 does not include a joining ring 116 at least prior to encapsulation. For example, an epoxy may be applied to the encapsulation lid 110 only without applying any epoxy to the device substrate 100 prior to joining. The device substrate 100 can include a joining area surrounding the MEMS device to which an encapsulation lid 110 will be joined.

In some implementations, the device substrate 100 includes bond pads 114 for connection to another component, such as a PCB or the like. The bond pads 114 may be any appropriate electrically conductive materials. Examples of appropriate metals include nickel (Ni), nickel/gold (Ni/Au), nickel/palladium (Ni/Pd), nickel/palladium/gold (Ni/Pd/Au), copper (Cu) and gold (Au). As with the joining ring 116, the metallization of the bond pads 114 is typically different that than used for a removable layer. In some implementations in which the joining ring 116 is metal, the bond pads 114 and joining ring 116 are the same material and may be formed in the same metallization operation.

In some implementations the device substrate 100 includes metal feed-throughs 118 to provide electrical connection from the MEMS device 106 to bond pads 114 or other components outside the encapsulation lid 110. The metal feed-throughs 118 pass from the MEMS device 106 under the joining ring 116, if present, to the bond pads 114 or other components.

Formation of the joining ring 116, bond pads 114, metal feed-throughs 118 and other components of the device substrate 100 can occur as part of the MEMS fabrication process, or prior to or after the MEMS fabrication process. Moreover, in some implementations, bond pads 114 and/or other desired components can be formed after encapsulation.

In some implementations, the joining ring 116 and/or bond pads 114 are built up to a certain height above the surface of the underlying substrate 102. For example, they can be built to the height of the MEMS device. FIG. 14 provides an example of a cross-sectional schematic illustration of an implementation of a device substrate. In FIG. 14, the joining ring 116 and bond pads 114 are built up to the height of the MEMS device 106. In some implementations, the joining ring 116 includes a metal 160 structure, for example, Ni or other material, and a solderable material 162 for joining to an encapsulation lid (not shown in FIG. 14). In the example of FIG. 14, the bond pad 114 includes a solderable material 162 for joining to a metal structure on the cover plate to further increase the height of the bond pad.

The implementation depicted in FIG. 14 may be useful, for example, in encapsulating tall MEMS structures, such as those that are at least 30-50 microns tall. As indicated above, the joining ring 116 and the bond pads 114 can be fabricated during fabrication of the MEMS device 106 on the substrate 102. In some implementations, the joining ring 116, the bond pads 114 and the MEMS device 106 can be plated in the same plating operation. Building up the joining ring 116 can reduce the height that the encapsulation lid structure extends above the cover plate. This is because the joining ring 116 can provide at least the height to accommodate the MEMS 106 device that otherwise may be provided by walls of the encapsulation lid structure. Building up the bond pads can increase the accessibility of the bond pads and facilitate flip-chip attachment to another substrate or wire bonding. In some implementations, only one of the joining area and bond pads is built up to the level of the MEMS device or to another level.

FIG. 15 shows an example of a flow diagram illustrating a process for forming a cover plate. An overview of a process for forming a cover plate is shown in FIG. 15, with examples of particular implementations of processes for forming cover plates described below with respect to FIGS. 16-22. The process 170 begins at block 172 with an optional operation of forming recesses in the carrier substrate. Prior to this process, in some implementations the carrier substrate is planar, having substantially uniform surfaces. In some implementations, recesses are created in which the encapsulation lids are later formed. One such example is depicted in FIG. 11B, in which a portion 111 of the encapsulation lid 110 is formed in a recess of the carrier substrate 112. In some other implementations, recesses are not formed and the encapsulation lids can be built up from a planar surface, or the carrier substrate may be provided with recesses already formed. Methods of forming recesses include wet etching, dry etching, sandblasting, stamping and embossing. In some implementations, a carrier substrate with or without recesses can be formed from injection molding plastic.

The process continues at block 174 in which a removable layer is formed on the surface of a carrier substrate on which the lids are to be formed. The removable layer may be made of any material that can be removed from at the least the encapsulation lids during a release operation without significant damage to the encapsulation lids. The removable layer may or may not be consumed during a release operation. In some implementations, the removable layer is made of a material that can be removed from the carrier substrate as well as the encapsulation lids. Examples of removable materials include a copper-based sacrificial layer, selectively removable from a Ni-based lid using an ammoniacal-based etch chemistry or an acrylic sacrificial layer removable by laser irradiation. More generally, the removable material can include a sacrificial layer that is selectively removable or etchable relative to the other structures such as the carrier substrate and the subsequently formed lids. Additional examples include an aluminum-based materials and dielectric-based materials. Aluminum-based materials can be selectively removed using a high pH alkaline etchant such as sodium ferricyanide, potassium ferricyanide, sodium permanganate, potassium permanganate or sodium persulfate. Examples of dielectric-based materials include inorganic dielectrics such as Al₂O₃, removable with a high pH alkaline etchant, and organic dielectrics such as polyimides and other polymers, removable with laser ablation.

Forming the removable layer may be performed by any process appropriate for the material including PVD processes such as pulsed laser deposition (PLD), sputter deposition, electron beam physical vapor deposition (e-beam PVD) and evaporative deposition, CVD processes including PECVD, ALD processes, spin-coating and lamination. The removable layer generally conformally coats the surface of the carrier substrate on which it is deposited. Accordingly, the removable layer can be substantially planar if formed on a substantially planar carrier substrate surface, or can follow recesses or other features of the underlying carrier substrate surface. An acrylic adhesive, for example, can be laminated on a planar carrier substrate surface.

In some implementations, the removable layer is formed as a blanket unpatterned layer on surface of carrier substrate on which the encapsulation lids are to be formed. In other implementations, the removable layer may be formed only in the areas of the carrier substrate on which the encapsulation lids are to be formed.

The process 170 continues at block 176 with formation of bases and walls of the encapsulation lids. The base of an encapsulation lid is the part of the lid that, when joined to the device substrate, covers the MEMS device, spanning the area over the MEMS device. In some implementations, it is substantially planar. It may be any appropriate material able to span the area over the MEMS device. Examples of encapsulation lid materials include metals, ceramics, glasses and plastics. Examples of metals include nickel (Ni), nickel (Ni) alloys, copper (Cu), copper (Cu) alloys, aluminum (Al), aluminum (Al) alloys, tin (Sn), tin (Sn) alloys, titanium (Ti) and titanium (Ti) alloys. Examples of ceramics include oxides, carbides, borides, nitrides, silicides and composite ceramics. Further examples include silicon-based materials such as silicon (Si), silicon dioxide (SiO₂) and silicon carbide (SiC).

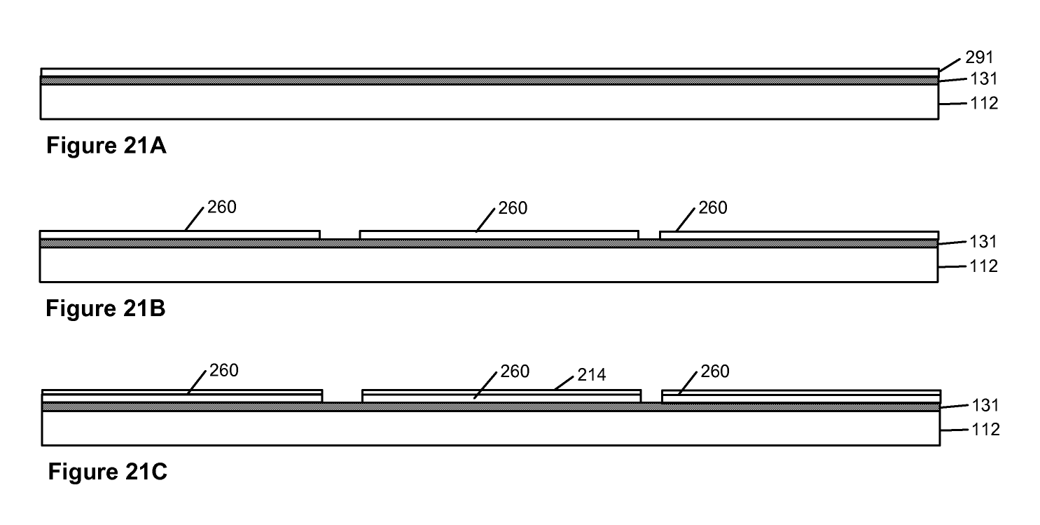

The walls of an encapsulation lid are the part of the lid that will eventually be attached to the device substrate and support the base of the lid. The thickness or height of the walls is sufficient to provide clearance for the MEMS device. In some implementations, forming the walls includes forming one or more structural support posts in addition to the walls. The walls can be made from the same material or a different material from the base, according to the desired implementations. For example, in some implementations, the base and walls are a Ni-based material. In some other implementations, composite encapsulation lids having a base and lids made of different materials, such as a metal and a dielectric, can be formed. For example, a Ni/SiC or Ni/SiO₂ encapsulation lid, including Ni walls and a SiC or SiO₂ base, may be used depending on the desired implementation. Forming composite encapsulation lids is discussed further below with respect to FIG. 20.

In some implementations, the base and/or walls of the encapsulation lids are made from an application-specific material. For example, in some implementations, the base and/or walls of the encapsulation lids are transparent to one or more types of electromagnetic radiation including ultraviolet (UV) and infra-red (IR) radiation. This can allow an encapsulated device to be interrogated, stimulated or inspected according to the desired implementation. For example, an IR-transparent encapsulation lid can be used to encapsulate a bolometer.

Forming the encapsulation lid, including the base and the walls, may involve any number of depositing, coating, molding, patterning, lithography, etching and operations according to the desired implementation. For example, metal encapsulation lids can be formed with processes including plating or vapor deposition. Glass encapsulation lids can be formed with processes including spin-on coating. Ceramic encapsulation lids can be formed with vapor deposition processes. The bases and walls of the encapsulation lids can be formed in the same or different process according to the desired implementation.

The process 170 continues at block 178 with an optional operation of adding joining material to the top of the walls. Joining material may include a solderable metallurgy, a solder paste, an epoxy or other adhesive. Adding joining material may involve plating, screen printing, dispensing or other methods. In some implementations, adding joining material may be performed during or as part of forming the walls in block 178. In some implementations, the joining material is added only to the device substrate and is not added to the encapsulation lids. In some implementations, the joining material is added only to one, or the other, of the device substrate and the encapsulation lids, but not both.

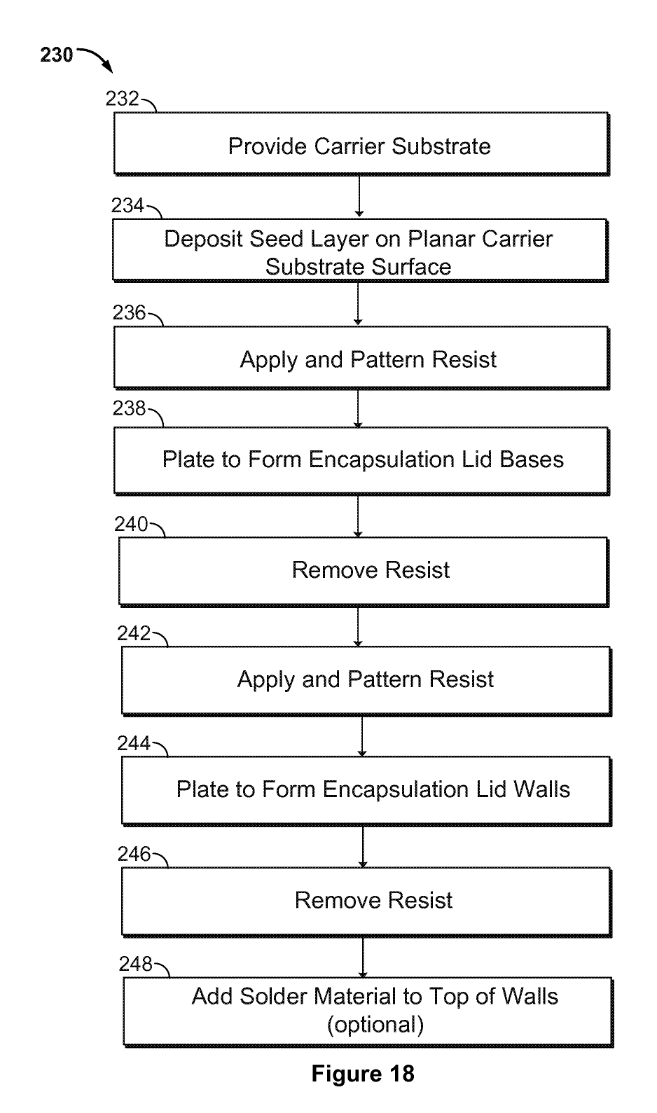

FIG. 16 shows an example of a flow diagram illustrating a process for forming a cover plate. FIGS. 17A-17E show examples of cross-sectional schematic illustrations of various stages in a method of forming a cover plate. Turning first to FIG. 16, a process 190 begins at block 192 with providing a glass carrier substrate. Thickness of the glass carrier substrate may range from about 0.1 mm to about 1.1 mm. In some implementations, the glass carrier substrate is substantially planar having substantially planar opposing surfaces. The process continues at block 194 with optionally etching the glass substrate to form recesses in a surface. In some implementations, a glass carrier substrate is provided with recesses already formed and process 190 moves from block 192 to 196, skipping block 194. For implementations where the recess is first formed in the glass carrier substrate, one recess is formed for every encapsulation lid to be attached to the carrier substrate, with the recesses shaped and sized to match the desired encapsulation lid size. The recesses are deep enough to provide clearance for the encapsulation lid over the MEMS device. Accordingly, the depth may depend on the heights of the MEMS devices to be encapsulated. In some implementations, the recesses are about 10-50 microns deep, although shallower or deeper recesses may be formed according to the desired implementation. Recess area varies according to the size of the MEMS devices to be encapsulated and can be arbitrarily large. In some implementations, an area is between about 1 square micron to about 100 square millimeters. In some implementations, an area may be larger, with length and width dimensions each centimeters, tens of centimeters, or greater. As discussed further below, the use of structural support posts and/or thick encapsulation lids can facilitate encapsulating large area MEMS devices including IMODs.

The substrate is masked appropriately prior to etching, with the mask removed after etching. For wet etching, mask materials may include photoresist, deposited layers of polysilicon or silicon nitride, silicon carbide or thin metal layers of chrome, chrome and gold or other etch-resistant material. Wet etch solutions include hydrogen fluoride based solutions, such as concentrated hydrofluoric acid (HF), diluted HF (HF:H₂O), buffered HF (HF:NH₄F:H₂O) or other suitable etchant with reasonably high etch rate of the glass substrate and high selectivity to the masking material. The substrate may be placed in the wet etchant or the wet etchant may be applied. The etchant also may be applied by spraying, puddling or other known techniques. In some implementations, a dry etch process can be used. FIG. 17A is an example of a cross-sectional illustration of a portion of a carrier substrate 112 including an etched recess 210 in a surface 212.

The process 190 continues at block 196 with conformal deposition of a seed layer on the carrier substrate surface that includes the recesses. A seed layer provides a conductive substrate on which a metal is plated. In this implementation, the seed layer acts as a removable layer as well as a seed layer for subsequent plating of the encapsulation lids. In some implementations, an adhesion layer is conformally deposited on the glass surface prior to deposition of the seed layer as known to one having ordinary skill in the art. For example, for a copper (Cu) seed layer, examples of adhesion layers include chromium (Cr), titanium (Ti), and titanium tungsten (TiW). The adhesion layer and seed layer may be deposited by sputter deposition though other conformal deposition processes may be used. In some implementations, the adhesion and seed layers are deposited without breaking vacuum. Example thicknesses of the adhesion layer range from about 100 to about 500 Angstroms, or more particularly from about 150 to 300 Angstroms, though one having ordinary skill in the art will understand that the adhesion layer can be thinner or thicker according to the implementation. Example seed layer thicknesses range from 800 Angstroms to 10,000 Angstroms, or more particularly from about 1,000 Angstroms to about 5,000 Angstroms, though the seed layer can be thinner or thicker according to the desired implementation. In one example, a Cr/Cu layer having a thickness of 150 Angstroms Cr and 1,000 Angstroms Cu is deposited.

In some implementations in which the seed layer is also the removable layer, the seed layer is a metal that has high etch selectivity for the metal used in the MEMS device or on the device substrate as well as metal used to form the encapsulation lids. For example, a Cu seed layer may be used where Al and/or Ni is used in the MEMS device, on the device substrate or for the encapsulation lids. In one example, a Cu seed layer can be used as removable layer and as a seed layer for a Ni or Ni alloy encapsulation lid. In some other implementations, different materials may be used for the removable layer and seed layer. For example, Al can be used as a removable layer with Cu used as a seed layer for a Cu encapsulation lid. Further examples of metallurgies and selective etchants are given below. FIG. 17B is an example of a cross-sectional illustration of a portion of a carrier substrate 112 including a Cr/Cu seed layer 214 conformally coating the etched surface 212.

The process 190 continues at block 198 with application and patterning of a resist. The resist is applied on the carrier substrate surface and patterned to define the areas of the substrate surface on which the encapsulation lids will be formed. Any appropriate resist known to one of having ordinary skill in the art can be used. In some implementations, a resist that tents over the etched cavities is used. This is so that after resist patterning, the cavities are substantially free of resist and resist-related residue. One example of such a resist is DuPont® MX5000 dry film photoresist, which is applied to the substrate surface by lamination. Other resists may be used including dry film, liquid and epoxy-based resists. The resist can be patterned by techniques including masked exposure to radiation and chemical development.

FIG. 17C is an example of a cross-sectional illustration of a portion of a carrier substrate 112 including a Cr/Cu seed layer 214 conformally coating the etched surface 212, and a patterned resist 216 overlying portions of the Cr/Cu seed layer 214 to define a plating area.

Returning to FIG. 16, the process 190 continues at a block 200 with plating to form the encapsulation lids. The encapsulation lids can be plated using electroless plating or electroplating as appropriate for the material used in the particular implementation. In some implementations, Ni is plated by electroless plating. The thickness of the plated lid material may vary according to the desired implementation, with example thicknesses ranging from about 5-20 microns. In some implementations, the base and walls of the encapsulation lid can be formed in a single plating operation. In one example, between about 8 and 18 microns of Ni is plated to form the base and walls of the encapsulation lids. In addition to Ni, materials that can be plated to form the encapsulation lids include Ni alloys such as nickel-cobalt (NiCo), nickel-iron (NiFe) and nickel-manganese (NiMn) or a combination of cobalt (Co) and iron (Fe).

The encapsulation lid material can depend on the area of the MEMS device to be encapsulated, with more rigid materials used for larger areas to ensure structural integrity of the encapsulation lid.

In some implementations, operation 200 includes plating a solderable metal on top of the main material that forms the encapsulation lids. For example, in some implementations, a thin gold (Au) layer is plated. In some implementations, between about 0.1 and 1 micron, for example about 0.3 microns, of a solderable metal is plated. It should be noted that in some implementations while solder material can be added to a plated metal (or other material), it may be useful in other implementations to avoid plating metal on a solder material.

The process 190 then continues at block 200 with stripping the resist. The resist is stripped by a technique appropriate for the particular resist used. Additionally, block 200 can include post-strip cleanse of resist-related residue.

FIG. 17D is an example of a cross-sectional illustration of a portion of a cover plate 108 including carrier substrate 112, removable layer 131 and encapsulation lid 110. It is noted that, in the implementation shown in FIG. 17D, the seed layer 214 of FIG. 17B now serves as the removable layer 131. Encapsulation lid 110 includes a Ni layer 220 and a thin Au layer 218. The walls of encapsulation lid 110 include a flange 113 as described above with respect to FIG. 11B. The process 190 continues at a block 204 with the addition of a solder material to the top of the walls. Solder material can be screen-printed or plated according to the desired implementation. If plated, a dry laminate resist that tents over the cavity, can be used to define a plating area.

FIG. 17E is an example of a cross-sectional illustration of a portion of a cover plate 108 including carrier substrate 112, removable layer 131 and encapsulation lid 110. A joining material 222, which is a solderable material in this implementation, on top of the flange 113 surrounds the recess 210. At this stage the cover plate is ready for joining to a device substrate.

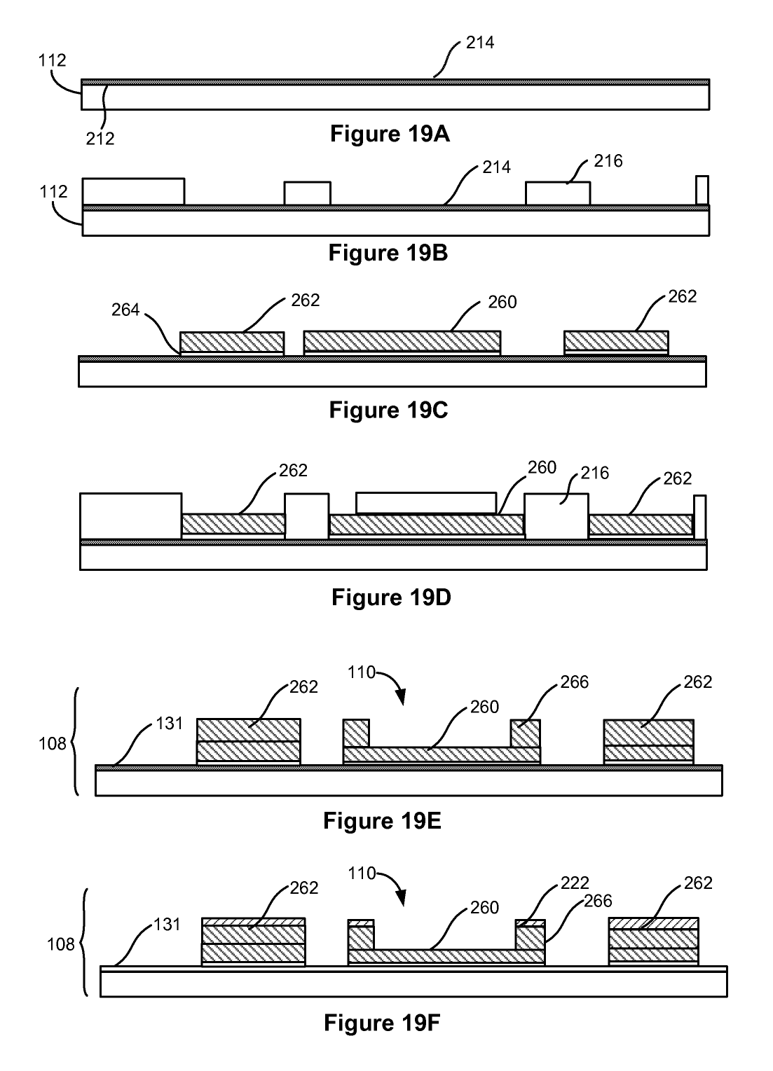

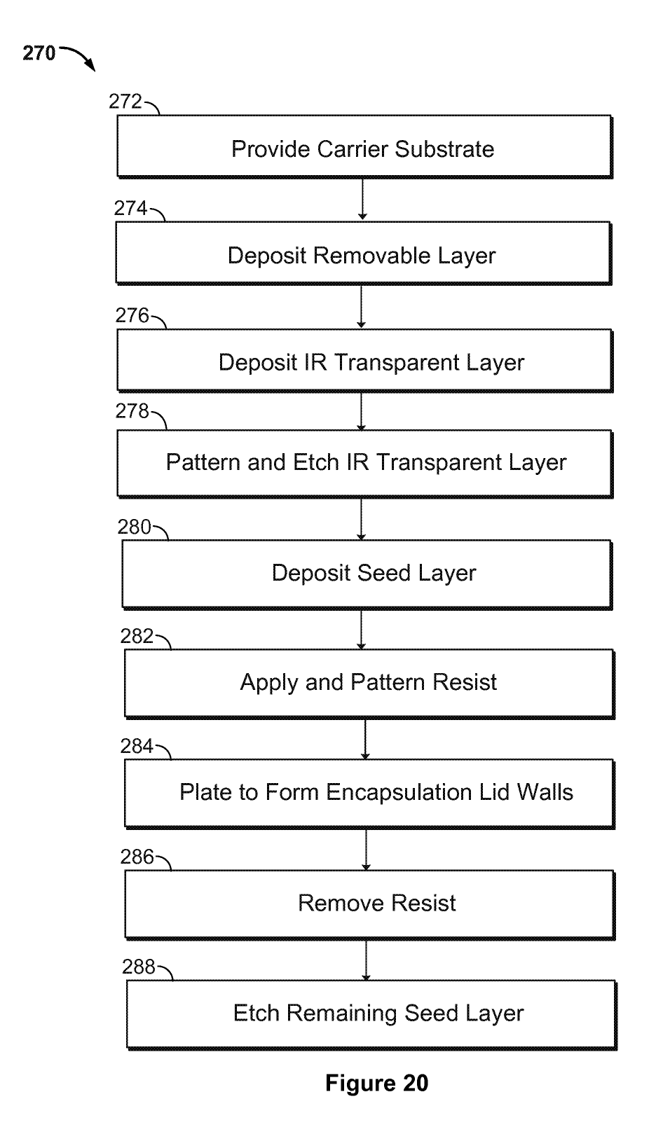

In some implementations, a cover plate fabrication process involves building up the encapsulation lids from a planar surface, rather than conformally plating metal in recessed cavities. FIG. 18 shows an example of a flow diagram illustrating a process for forming a cover plate. FIGS. 19A-19F show examples of cross-sectional schematic illustrations of various stages in a method of forming a cover plate. Turning first to FIG. 18, a process 230 begins at a block 232 by providing a carrier substrate. In some implementations, the carrier substrate is glass. Thickness of the glass carrier substrate may range from about 0.1 to 1.1 mm in some implementations, though thinner or thicker carrier substrates can be used. In the illustrated implementation, the carrier substrate is substantially planar having substantially planar opposing surfaces. The process continues at a block 234 with deposition of a seed layer on a planar surface of the carrier substrate. The seed layer is deposited on the surface of the carrier substrate to which the lids will be attached. As in process 190 described above with reference to FIG. 16, the seed layer can act as the removable layer as well as a seed layer for subsequent plating of the encapsulation lid bases.

In some implementations, an adhesion layer is deposited on the glass surface prior to deposition of the metal layer. Examples of adhesion and seed layers that can be used are given above with respect to FIG. 16. FIG. 19A is an example of a cross-sectional illustration of a portion of a carrier substrate 112 including a Cr/Cu seed layer 214 coating surface 212. Unlike the process 190 described above with respect to FIG. 16, the surface 212 on which the seed layer is deposited in this implementation is substantially planar without etched recesses.

The process continues at block 236 with application and patterning of a resist. The resist is patterned to define encapsulation lid bases. In some implementations, the resist is further patterned to define bond pad extensions. This operation can involve various application, masked exposure and development operations according to the desired implementation. Any appropriate resist may be used including dry film, liquid and epoxy-based resists. FIG. 19B is an example of a cross-sectional illustration of a portion of a carrier substrate 112 including a Cr/Cu seed layer 214 coating the planar surface 212, and a patterned resist 216 overlying portions of the Cr/Cu seed layer 214 to define a plating area.

The process 230 continues at block 238 with plating to form the encapsulation lid bases. The encapsulation lid bases can be plated using electroless plating or electroplating as appropriate for the material used in the particular implementation. In some implementations, nickel is plated by electroless plating. The thickness of the plated base may vary according to the desired implementation, with example thicknesses ranging from about 2 to 20 microns. As described above, the base of an encapsulation lid spans the area over the MEMS device. Accordingly, the thickness is sufficient to provide structural integrity. In one example, a nickel layer of between about 3 and 15 microns is plated. As described above with reference to FIG. 16, in addition to Ni, materials that can be plated to form the encapsulation lids include Ni alloys such as nickel cobalt (NiCo). In some implementations, a solderable metallurgy is plated at the bottom of bond pad extensions. This is because once the lids and bond pads are flipped, the bottom of the bond pad extensions will be bond pads, and the area to which wires or other external connections may be soldered. In some implementations, a thin layer of gold (Au), palladium (Pd) or other solderable metallurgy is plated on the seed layer prior to forming a Ni base and bond pad extensions.

The process continues at a block 240 with removal of the resist by an appropriate method. FIG. 19C is an example of a cross-sectional illustration of a portion of a carrier substrate 112 including an encapsulation lid base 260 made of Ni, and Ni bond pad extensions 262. A thin layer 264 of Pd underlies the encapsulation lid base 260 and Ni bond pad extensions 262. The thin layer of Pd 264 facilitates flip-chip attachment or other solder connection to bond pad extensions 262 in some implementations.

The process 230 continues at block 242 with application and patterning of a resist. This additional patterning operation defines the plating area to plate the walls of the encapsulation lid. In some implementations, the resist is also patterned to define bond pad extensions. FIG. 19D is an example of a cross-sectional illustration of a portion of a carrier substrate 112 including a Cr/Cu seed layer 214 coating surface 212, and a patterned resist 216 overlying portions of the Cr/Cu seed layer 214 and the Ni encapsulation lid base 260 to define a plating area.

The process 230 continues at block 244 with plating to form the walls of the encapsulation lids. In some implementations, bond pad extensions are plated during this operation as well. Plating is performed to a thickness sufficient to provide clearance for the MEMS device. In some implementations, the walls are about 3 to 20 microns tall, for example, between about 3 and 8 microns tall. (Non-uniformity in plating thickness across a substrate increases with thickness. This can become an issue at plating thicknesses of greater than about 20 microns. If additional height is desired to provide adequate clearance for the MEMS device, it can be provided by a raised joining ring as depicted in FIG. 14 and/or by using additional solder material during the joining operation.) At this stage, the cover plate including encapsulation lids releasably attached to a carrier substrate is formed. The process 230 continues at block 246 with removal of the resist.

FIG. 19E is an example of a cross-sectional illustration of a portion of a cover plate 108 including carrier substrate 112, removable layer 131 and encapsulation lid 110. Encapsulation lid 110 includes encapsulation lid base 260 and encapsulation lid walls 266. In the depicted example, cover plate 108 also includes bond pad extensions 262.

The process can continue at block 248 with the addition of solder material to the top of the walls. Block 248 is optional and can depend on the particular joining method used. In some implementations, a solder paste is plated or screen printed on the top of the walls. In some implementations, a thin solderable metal such as gold (Au) is plated on the top of the walls. In some implementations, this operation may occur prior to removing the resist and after plating to form the walls in operation 244. In some implementations, a solder material is added to bond pad extensions. FIG. 19F is an example of a cross-sectional illustration of a portion of a cover plate 108 including carrier substrate 112, removable layer 131 and encapsulation lid 110. A joining material 222, which is a solder material in this implementation, is on the top of encapsulation lid walls 266 and bond pad extensions 262. At this stage the cover plate is ready for joining to a device substrate.

In the examples of FIGS. 16 and 18, the seed layer acts as the removable layer. In some other implementations, a seed layer is deposited on a separate removable layer that is on the carrier substrate surface. For example, in some implementations, a thin Cu layer is a removable layer, with an Au, Ni or Ni alloy layer used as a seed layer for plating a Ni or Ni alloy lid. An adhesion layer such as Cr or Ti can be used between the Cu removable layer and the seed layer. In one example, a bilayer including a 300 Å Ti or Cr adhesion layer and a 800 Å Au seed layer is deposited on a Cu removable layer. In another example, a bilayer including a 300 Å Ti or Cr adhesion layer and a 1000 Å Ni or Ni alloy seed layer is deposited on a Cu removable layer. The Cu removable layer can be selectively etched with an etchant such as a mixture of acetic acid (CH₃CO₂H) and hydrogen peroxide (H₂O₂) or an ammoniacal-based etchant such as BTP copper etchant from Transene Company, Inc. in Danvers, Mass. These etchants selectively etch Cu without etching Ni, Ti, Cr, or Au or alloys thereof.

In another example, a thin Al layer is a removable layer, with a Cu, Au, Ni or Ni alloy layer used as a seed layer for plating a Ni or Ni alloy lid. An adhesion layer such as Cr or Ti can be used between the Al removable layer and the seed layer. In one example, a bilayer including 300 Å Ti or Cr adhesion layer and an 800 Å Au seed layer is deposited on an Al removable layer. In another example, a bilayer including a 300 Å Ti or Cr adhesion layer and a 1000 Å Cu or Ni or Ni alloy seed layer is deposited on an Al removable layer. The Al removable layer can be selectively etched with an etchant such as an alkaline etchant for Al, which can selectively etch Al without etching Cu, Ni, Ti, Cr, or Au or alloys thereof.

In another example, a thin oxide of Al layer is a removable layer, with a Cu, Au, Ni or Ni alloy layer used as a seed layer for plating a Ni or Ni alloy lid. A Ti adhesion layer can be used between the oxide of Al removable layer and the seed layer. In one example, a bilayer including a 300 Å Ti adhesion layer and a 800 Å Au seed layer is deposited on an oxide of Al removable layer. In another example, a bilayer including a 300 Å Ti adhesion layer and a 1000 Å Cu or Ni or Ni alloy seed layer is deposited on an oxide of Al removable layer. The oxide of Al removable layer can be selectively etched with a phosphoric acid based etchant or an alkaline etchant with an oxidizer such as ferricyanide or permanganate. These etchants selectively etch oxides of Al without etching Ni, Ti, Au or Cu.

In another example, a laser-cleavable polymer sacrificial layer is a removable layer with a Cu, Au, Ni or Ni alloy layer used as a seed layer for plating a Ni or Ni alloy lid. An adhesion layer such as Cr or Ti can be used between the polymer removable layer and the seed layer. In one example, a bilayer including a 300 Å Ti or Cr adhesion layer and a 800 Å Au seed layer is deposited on a polymer removable layer. In another example, a bilayer including a 300 Å Ti or Cr adhesion layer and a 1000 Å Cu or Ni or Ni alloy seed layer is deposited on a polymer removable layer. The polymer removable layer can be selectively removed by laser ablation without damage to any of the metals.

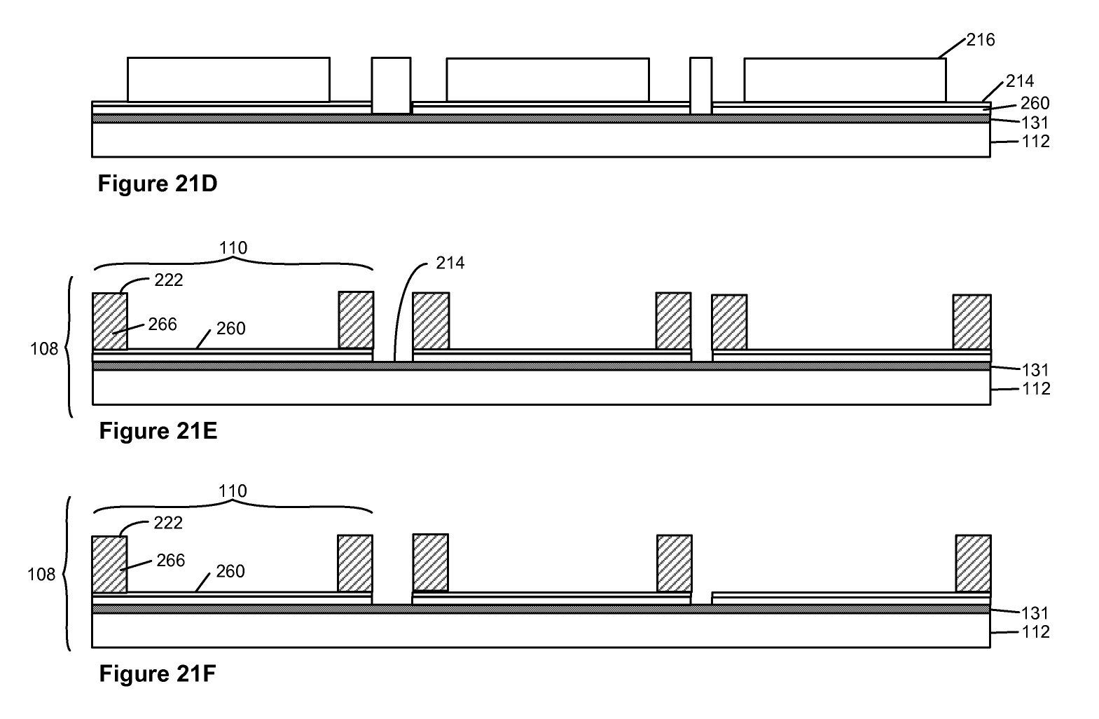

In some implementations, a cover plate fabrication process involves forming an encapsulation lid tailored for a particular device. The encapsulation lid base and/or walls can be formed to provide a functional characteristic. Examples include encapsulation lids that are transparent to certain types of radiation. FIG. 20 shows an example of a flow diagram illustrating a process for forming a cover plate including encapsulation lids for bolometers. A bolometer is a device for measuring the energy of incident electromagnetic radiation via, in some implementations, the heating of an absorptive element, such as a thin film of metal, by absorption of the incident radiation. In some implementations, an encapsulation lid for a bolometer is infrared (IR) transparent. FIGS. 21A-21F show examples of cross-sectional schematic illustrations of various stages in a method of forming a cover plate including encapsulation lids for bolometers. Turning first to FIG. 20, a process 270 begins at block 272 with providing a carrier substrate. Examples of suitable carrier substrates are described above. The process continues at block 274 with deposition of a removable layer on a surface of the carrier substrate. The removable layer can be any appropriate material as described above including selectively etchable metal or dielectric layers, acrylic layers and the like. That is the removable layer can include various materials that are selectively removable or etchable relative to the other structures and layers such as the carrier substrate and layers that are subsequently deposited over the removable layer. After deposition of the removable layer, the process continues at block 276 with deposition of an IR transparent layer. Examples of IR transparent materials include silicon (Si), indium oxide (In₂O₃), sapphire, nickel-cobalt-lithium oxide (NiCoLiO₂), gallium phosphide (GaP), gallium-doped zinc oxide (Ga-doped ZnO), zinc selenide (ZnSe), polycarbonates and acrylics. Thickness of the IR transparent layer can range from about 10 microns to 100 microns depending on the materials and the size of the IR-transparent window, though the thickness may be outside this range according to the desired implementation. As described further below, the bases of the encapsulation lids are formed from the IR transparent layer, so the layer is thick enough to provide structural integrity to span the area over the bolometer. FIG. 21A is an example of a cross-sectional illustration of a portion a carrier substrate 112 including IR transparent layer 291 and removable layer 131 coating a surface of carrier substrate 112. In the depicted implementation, removable layer 131 and IR transparent layer 291 are blanket layers on carrier substrate 112. The process 270 continues at block 278 with patterning and etching the IR transparent layer to form the bases of the encapsulation lids. In some implementations, block 278 can be omitted, with the IR transparent layer separated during dicing of the encapsulated devices. FIG. 21B depicts carrier substrate 112 after formation of encapsulation lid bases 260. The process 270 continues at block 280 with the deposition of a seed layer for subsequent plating. Seed layer deposition is described above with reference to operation 196 of FIG. 16 and operation 234 of FIG. 18. In this implementation, the seed layer does not act as the removable layer. FIG. 21C depicts carrier substrate 112 after deposition of seed layer 214. In the depicted example, seed layer 214 is conformally deposited on the encapsulation lid bases 260 and surface of carrier substrate 112. The process 270 continues at block 282 with application and patterning of a resist. The resist is applied on the seed layer and is patterned to define the areas where the encapsulation lids walls are to be formed. Any appropriate resist can be used. FIG. 21D depicts carrier substrate 112 including patterned resist 216. Patterned resist 216 masks the interior of encapsulation lid bases 260 as well as the area between the encapsulation lid bases 260. The process 270 continues at block 284 with plating to form the encapsulation lids walls. Example metals, including Ni and Ni alloys, that can be plated to form encapsulation walls are described above. Plating is performed to a thickness sufficient to provide clearance for the MEMS device. In some implementations, the walls are about 3 to 20 microns tall, for example, between about 3 and 8 microns tall. In some implementations, bond pad extensions also are plated during this block in process 270 (not shown in FIG. 21E). Also in some implementations, a joining material is plated on top of the walls. Joining material may be screen-printed or otherwise applied in a subsequent operation as described above. The process 270 continues at block 286 with removal of the resist. FIG. 21E depicts carrier substrate 112 after resist removal. At this stage, the cover plate 108 is formed including encapsulation lids 110 releasably attached to carrier substrate 112 by removable layer 131. Each encapsulation lid 110 includes an encapsulation base 260, which is IR transparent, and encapsulation lid walls 266. A joining material 222 is plated on top of encapsulation lid walls 266. In one example, Ni, Au and solder are plated sequentially to form encapsulation lid walls 266 and joining material 222. Seed layer 214 remains between encapsulation lids 110. The process 270 continues at block 288 with etching of the remaining seed layer. Etching of the remaining seed layer is performed with an etchant that is selective to the seed layer, without etching encapsulation lid walls 266 or removable layer 131. FIG. 21F depicts cover plate 108 including encapsulation lids 110 releasably attached to carrier substrate 112. Removable layer 131 is exposed between encapsulation lids 110.

The encapsulation lids formed by the process 270 described in FIG. 20 are examples of composite encapsulation lids, having metal walls and IR-transparent bases. The process 270 can be adapted to form other types of composite lids, including composite metal/dielectric lids. For example, block 276 can be modified to a dielectric material such as silicon carbide (SiC) or silicon nitride (SiN).

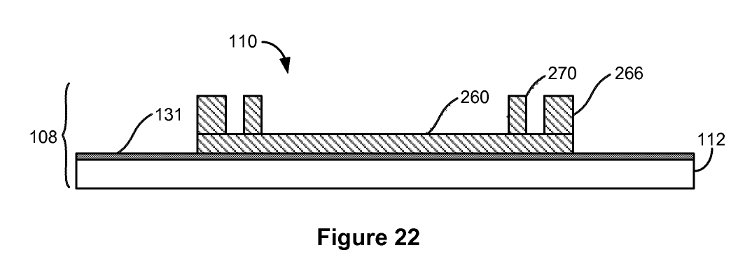

As indicated above, in some implementations, the encapsulation lid includes structural support posts. FIG. 22 is an example of a cross-sectional illustration of a portion of a cover plate including an encapsulation lid with structural support posts. Cover plate 108 includes carrier substrate 112, removable layer 131 and encapsulation lid 110. The encapsulation lid 110 includes structural support posts 270, which are disposed on the encapsulation lid base 260 and are interior to the encapsulation lid walls 266. In some implementations, structural support posts can be formed in the same operation as the encapsulation lid walls. In other implementations, they can be formed prior to or after formation of the walls according to the desired implementation.

Once the device substrate and cover plate are fabricated, the encapsulation lids on the cover plate can be aligned and joined to the device substrate. Aligning the cover plate and the device substrate can involve standard flip-chip placement techniques, including the use of alignment marks and the like. The cover plate is aligned such that one or more encapsulation lids of the cover plate are substantially aligned over one or more corresponding devices on the device substrate. In some implementations, the walls of each of the one or more encapsulation lids are aligned with a joining area surrounding a corresponding device on the device substrate. The use of panels, sub-panels or wafers in a batch level process allows alignment features to be created and standard wafer bonding tools and processes to be used in alignment.

Methods of joining the encapsulation lids to the device substrate include solder bonding including eutectic metal bonding and adhesive bonding including epoxy bonding. Solder bonding involves contacting the encapsulation lid walls and joining ring of a device substrate to a solder paste or other solderable material in the presence of heat. Eutectic metal bonding involves forming a eutectic alloy layer between the encapsulation lid and the device substrate. Examples of eutectic alloys that may be used include copper/tin (CuSn), gold/tin (AuSn), indium/silver (InAg), copper/tin/indium (CuSnIn) and copper/tin/bismuth (CuSnBi). As indicated above, in some implementations, a solder paste is applied to the joining rings on the device substrate and/or the tops of encapsulation lid walls. In some implementations, the joining rings on the device substrate and/or the tops of encapsulation lid walls are made of the appropriate metals to form a eutectic alloy when joined. Epoxy bonding involves contacting the encapsulation lid walls and the device substrate to an epoxy. Heat, radiation (such as ultraviolet radiation) or pressure may be applied to form the epoxy bond according to the desired implementation.

Joining process conditions such as temperature and pressure can vary according to the particular joining method and desired characteristics of the encapsulation area. For example, for eutectic or solder bonding, the joining temperature can range from about 100° C. to about 500° C. as appropriate. Example temperatures are about 150° C. for indium/bismuth (InBi) eutectic, about 225° C. for CuSn eutectic and about 305° C. for AuSn.

In some implementations, the joining operation involves setting a defined pressure in the encapsulated area. This may involve pumping a gas in or out of a chamber in which the joining occurs to set the desired pressure. In various implementations, after the joining operation, the pressure in the encapsulated area to which the MEMS device is exposed can be below atmospheric, above atmospheric or at atmospheric pressure. The composition of the gas also can be tailored to a desired composition. For example, a desired gas and pressure to, for example, damp a proof mass of a MEMS accelerometer can be dialed in during the joining process. Examples of gases include nitrogen, helium, neon, argon, xenon and combinations thereof.

Methods of releasing the carrier substrate include exposure to chemical etchants and laser irradiation. In some implementations, a Cu-based removable layer is exposed to a hydrogen peroxide (H₂O₂)-based etchant or other selective etchant. Selective etchants include etchants that have selectivity of at least about 100:1 or higher for the removable layer relative to other materials in the cover plate. For example, Cu:Ni etch selectivity in some etchants is about 1000:1. Specific examples of etchants for selective etching of Cu include a mixture of acetic acid (CH₃CO₂H) and H₂O₂ and ammoniacal-based etchant such as BTP copper etchant from Transene Company, Inc. In some other implementations, an Al-based removable layer is exposed to an alkaline etchant that etches Al selectively in the presence of Cu, Ni, Ti and Au. In some other implementations, oxides of Al can be used as a removable layer and selectively etched with an alkaline etchant including an oxidizer or a phosphoric acid-based etchant. In some other implementations, an adhesive acrylic or other polymer removable layer is removed by laser irradiation. Laser irradiation through a transparent substrate cleaves an acrylic adhesive, selectively removing an acrylic removable layer without affecting any part of the device substrate or encapsulation lids.

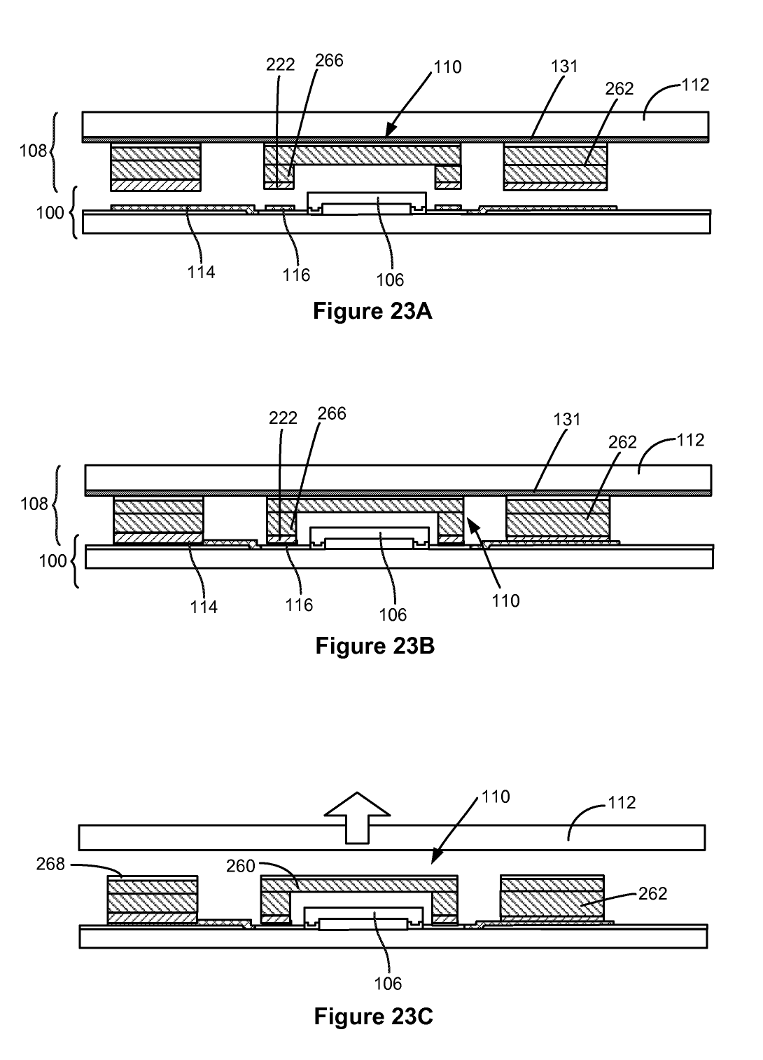

FIGS. 23A-23C and 24A-24C show examples of cross-sectional schematic illustrations of alignment and joining of encapsulation lids and release of a carrier substrate. First, in FIG. 23A, alignment of a portion of a cover plate 108, as depicted in FIG. 19F, with a device substrate 100 is shown. The cover plate 108 includes an encapsulation lid 110 releasably attached to a carrier substrate 112 by removable layer 131. The encapsulation lid 110 is aligned with the device substrate 100 such that the encapsulation lid walls 266 are positioned over joining ring 116 and bond pad extensions 262 are positioned over bond pads 114. Joining material 222 is disposed on the tops of the encapsulation lid walls 264 and on the tops of bond pad extensions 262. FIG. 23B shows joining of the encapsulation lid 110 to the device substrate 100. As shown, the cover plate 108 is brought into contact with the device substrate 100, or more specifically, the joining material 222 disposed on the tops of encapsulation lid walls 266 and bond pad extensions 262 are brought into contact with joining ring 116 and bond pads 114, respectively. Heat is applied, forming a solder bond between the encapsulation lid 110 and the joining ring 116 and between the bond pad extensions 262 and the bond pads 114. FIG. 23C shows release of carrier substrate 112 after joining. The MEMS device 106 is encapsulated by encapsulation lid 110, with base 260 of encapsulation lid 110 spanning the area over the MEMS device 106. The device substrate 100 includes encapsulated MEMS device 106 and bond pad extensions 262. Bond pad extensions include contact surfaces 268 to which wires or other components may be connected to establish an electrical connection to the MEMS device 106.

As described above with respect to FIG. 14, a device substrate having a built up joining ring may be used to for taller MEMS devices to allow a taller MEMS device to be encapsulated without having to increase the heights of the encapsulation lid walls. FIGS. 24A-24C show examples of cross-sectional schematic illustrations of alignment and joining of an encapsulation lid to a device substrate having a built up joining ring. First, FIG. 24A shows alignment of a portion of a cover plate 108 with a device substrate 100 as depicted in FIG. 14. Device substrate 100 includes a MEMS device 106, joining ring 116 and bond pads 114. The joining ring 116 and bond pads 114 are built up to the level of the MEMS device 106. The joining ring 116 includes a solderable material 162 for joining to encapsulation lid 110 of cover plate 108. Bond pad 114 also includes a solderable material 162 for joining to bond pad extensions 262 of cover plate 108. Solderable material 162 may be a plated solderable metallurgy, for example, Au, a solder paste or the like. The cover plate 108 includes an encapsulation lid 110 releasably attached to a carrier substrate 112 by removable layer 131. The encapsulation lid 110 is aligned with the device substrate 100 such that the encapsulation lid walls 266 are positioned over joining ring 116 and bond pad extensions 262 are positioned over bond pads 114. Joining material 222 is disposed on the tops of the encapsulation lid walls 266 and on the tops of bond pad extensions 262. Joining material 222 may be a plated solderable metallurgy, a solder paste or the like.

FIG. 24B shows joining of the encapsulation lid 110 to the device substrate 100. As shown, the cover plate 108 is brought into contact with the device substrate 100, or more specifically, the joining material 222 disposed on the tops of encapsulation lid walls 266 and bond pad extensions 262 are brought into contact with the solderable material 162 disposed on joining ring 116 and bond pads 114, respectively. Heat is applied, forming a solder bond between the encapsulation lid 110 and the joining ring 116 and between the bond pad extensions 262 and the bond pads 114. At this stage, the MEMS device 106 is encapsulated by encapsulation lid 110. FIG. 24C shows release of the carrier substrate 112 after joining. The MEMS device 106 is encapsulated by encapsulation lid 110, with the base 260 of the encapsulation lid 110 spanning the area over the MEMS device 106. The device substrate 100 includes encapsulated MEMS device 106 and bond pad extensions 262. Bond pad extensions include contact surfaces 268 to which wires or other components may be connected to establish an electrical connection to the MEMS device 106. In some implementations, bond pad extensions facilitate electrical flip-chip attachment as solder balls only have to reach the contact surfaces 268. FIG. 24C shows release of the carrier substrate 112 after joining. In some implementations, the carrier substrate 112 can be reused by attaching another set of encapsulation lids to cover MEMS devices on another device substrate.

Once the MEMS devices on a device substrate are encapsulated, if desired, the backside of the device substrate can be thinned. Individual dies can be formed by die singulation as described above with reference to FIGS. 13D and 13E. The individual dies, each having an encapsulated MEMS device, can be further packaged, for example with an ASIC.

FIG. 25 shows an example of a flow diagram illustrating a packaging process for a die including an encapsulated MEMS device, for example after singulation of encapsulated devices on device substrate. The process 300 begins at a block 302 with positioning of the die on a substrate, such as a PCB or other substrate to which the MEMS device is to be electrically connected. In some implementations, an ASIC also is positioned on the PCB or other substrate. The MEMS die and ASIC can be positioned in a side-by-side or stacked configuration. The process 300 continues at block 304 with wire bonding to form an electrical connection to one or more electrically active components, such as conductive pads, on the PCB or other substrate. At this stage, the MEMS device, and if present, an ASIC are electrically connected to the substrate. The process 300 continues at a block 306 with overmolding a mold material to cover the die and, if present, an ASIC. Further processing operations, including singulation of dies including the packaged MEMS device and ASIC can be performed, according to the desired implementation.

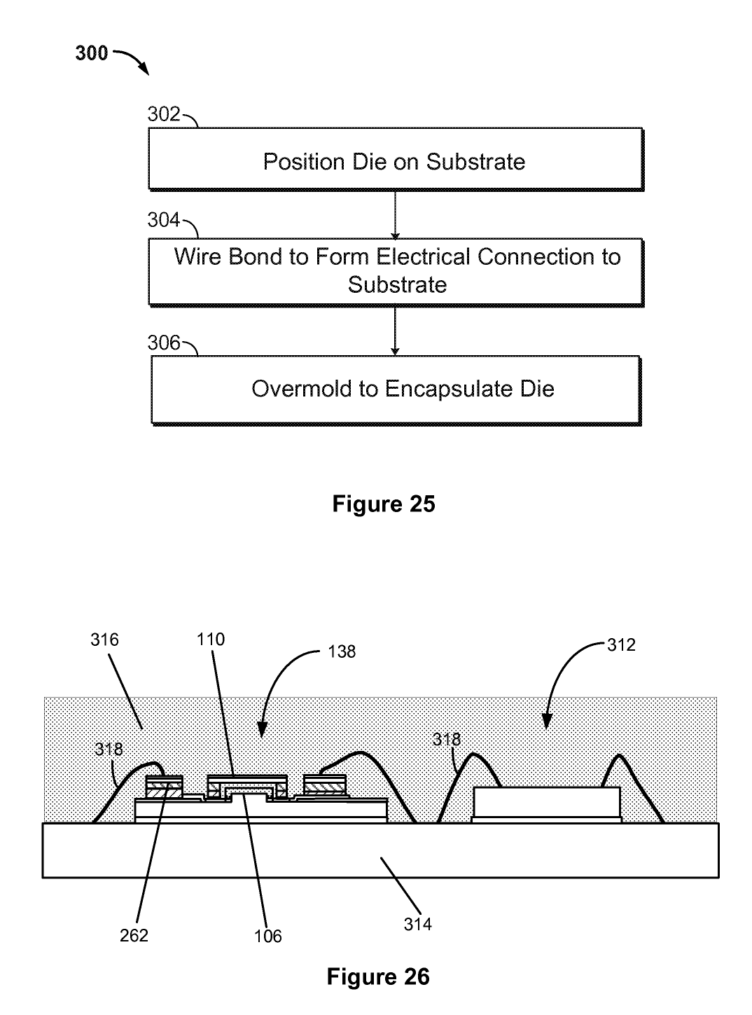

FIG. 26 shows an example of a cross-sectional schematic illustration of a packaged die including an encapsulated MEMS device and an ASIC on a PCB. Die 138 includes a MEMS device 106 encapsulated by an encapsulation lid 110. The MEMS device 106 is electrically connected to a PCB 314 by wires 318 bonded to bond pad extensions 262. The ASIC 312 is also connected to the PCB 314 by bonded wires 318. An overmold material 316 covers the die 138 and the ASIC 312 and protects wires 318.

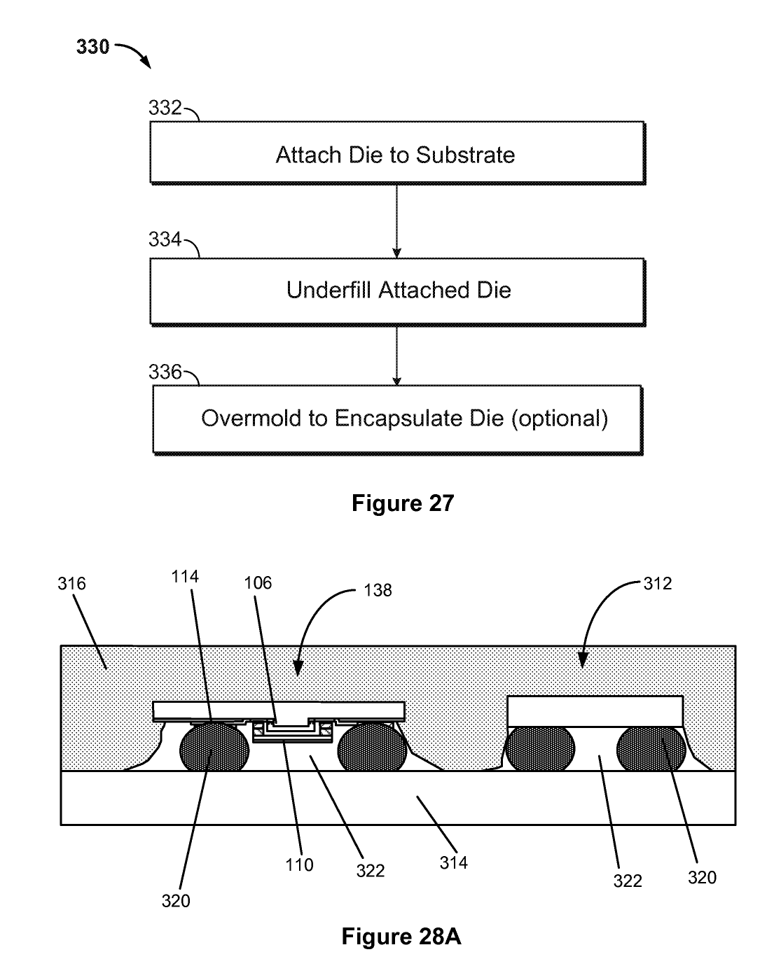

FIG. 27 shows another example of a flow diagram illustrating a packaging process for a die including an encapsulated MEMS device. The process 330 begins at block 332 with attachment of the die to a substrate, such as a PCB. In some implementations, an ASIC also is attached to the PCB or other substrate. Attachment can be performed by a flip-chip process in which solder balls are placed on bond pads of the die, the die is flipped such that the solder balls face the PCB, and the solder balls are melted to attach the die to the PCB, with the solder bond providing electrical connection to the bond pads and MEMS device of the die. The process continues at block 334 with underfilling the die with an electrically insulative adhesive material. If present, an attached ASIC also is underfilled. The process 330 continues at block 336 with overmolding a mold material to cover the die and, if present, an ASIC. Block 336 is optional and is not performed in some implementations. Further processing operations, including singulation of dies including both the packaged MEMS device and ASIC from other such dies on the PCB can be performed, according to the desired implementation. For example, multiple dies, each of which includes a MEMS device and an ASIC, can be on the PCB prior to singulation. These can be separated during singulation.

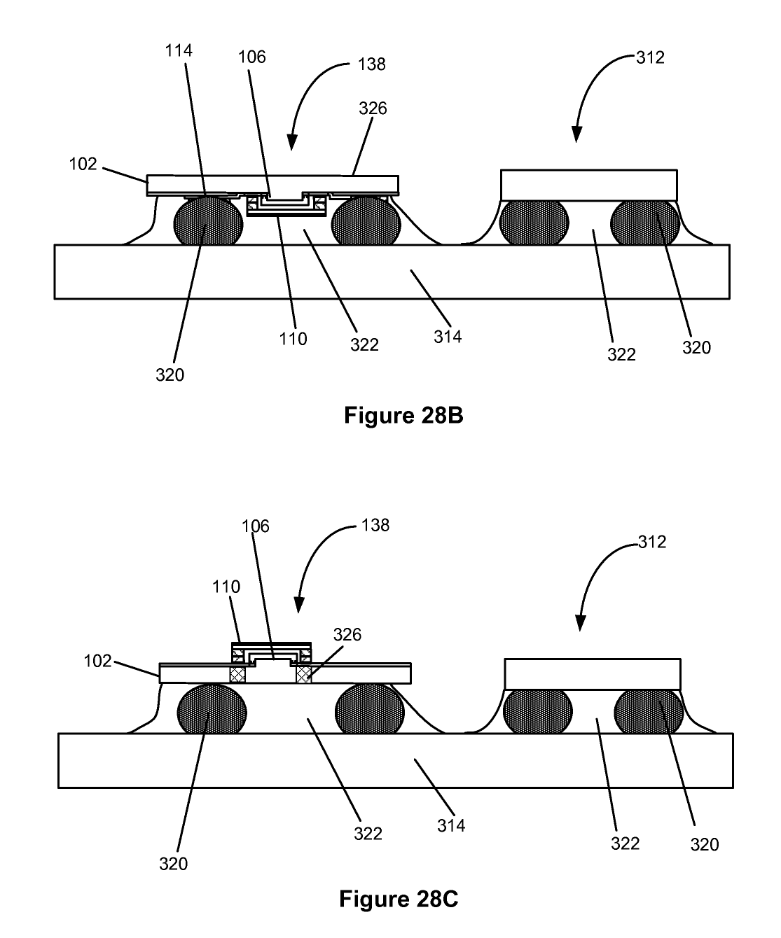

FIGS. 28A-28C shows examples of cross-sectional schematic illustrations of a flip-chip die including an encapsulated MEMS device and an ASIC on a PCB. In FIG. 28A, a die 138 includes a MEMS device 106 encapsulated by an encapsulation lid 110. The MEMS device 106 is electrically connected to a PCB 314 by solder bonds 320 that connect bond pads 114 on die 138 to circuitry (not shown) on PCB 314. An ASIC 312 also is connected to the PCB 314 by solder bonds 320. The die 138 and the ASIC 312 are underfilled with an underfill material 322. An overmold material 316 covers the die 138 and the ASIC 312. Notably, the small area that the encapsulation lid 110 occupies and the presence of bond pads 114 on the same surface of the die 138 as the MEMS device 106 allow flip-chip attachment without a through via providing electrical connection to the MEMS device 106 since bond pads 114 are provided on the same side of the device substrate 102 as the MEMS device 106.

In FIG. 28B, a die 138 includes a MEMS device 106 encapsulated by an encapsulation lid 110. The MEMS device 106 is electrically connected to a PCB 314 by solder bonds 320 that connect bond pads 114 on die 138 to circuitry (not shown) on PCB 314. An ASIC 312 also is connected to the PCB 314 by solder bonds 320. The die 138 and the ASIC 312 are underfilled with an underfill material 322. A substrate 102 of the die 138 is exposed with no overmold material disposed thereon. This can allow inspection, interrogation or stimulation of the MEMS device 106 through the substrate 102 in implementations where this can be useful.

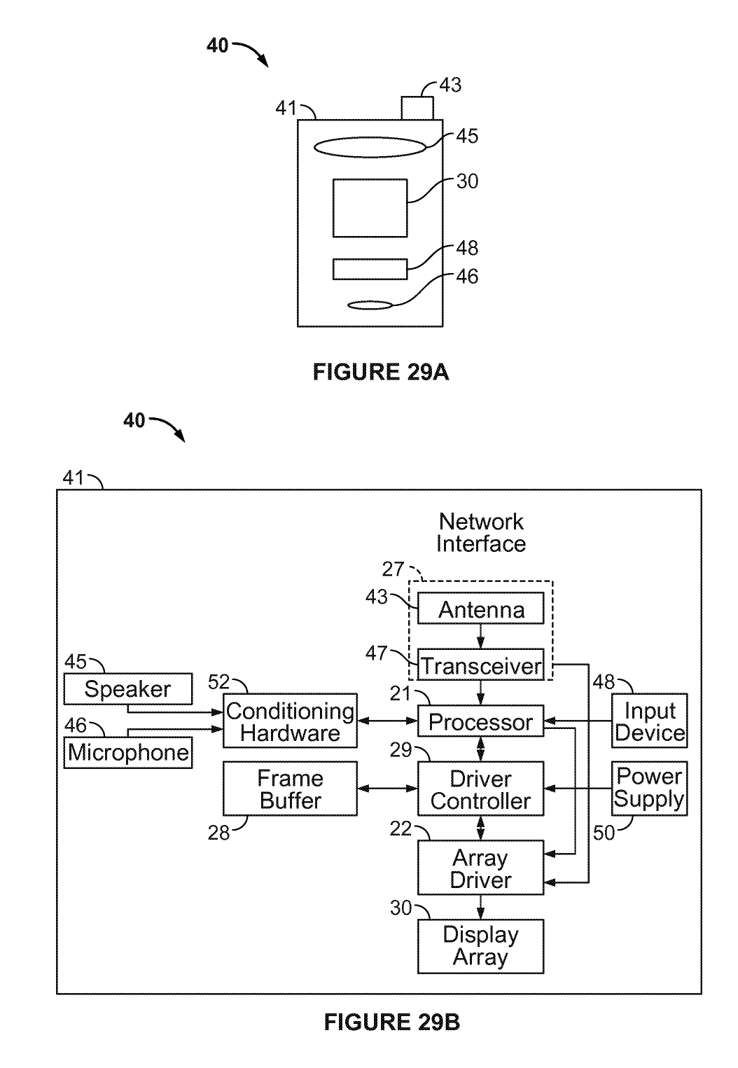

In FIG. 28C, a die 138 includes a MEMS device 106 encapsulated by an encapsulation lid 110. The die 138 also includes through-glass vias 326 in the substrate 102, illustrated in this example as a glass substrate. The MEMS device 106 is electrically connected to a PCB 314 by the through-glass vias 326, which are connected to solder bonds 320 by conductive leads (not shown). Solder bonds 320 are in turn connect bond pads (not shown) on die 138 to circuitry (not shown) on PCB 314. An ASIC 312 also is connected to the PCB 314 by solder bonds 320. The die 138 and the ASIC 312 are underfilled with an underfill material 322. In some implementations, the encapsulation lid 110 is transparent to electromagnetic radiation. This can allow inspection, interrogation or stimulation of the MEMS device 106 through the encapsulation lid 110. In the implementations described above, the PCB 314 can be any appropriate PCB, including a system board. In some implementations, the PCB 314 can be further attached to another PCB or other integration substrate. In some implementations, an encapsulated device as described herein can be part of a display device. In some other implementations, non-display devices fabricated on glass (or other transparent) substrates can be compatible with displays and other devices that are also fabricated on glass (or other transparent) substrates, with the non-display devices fabricated jointly with a display device or attached as a separate device, the combination having well-matched thermal expansion properties. Examples of non-display electromechanical devices that can be compatible with display devices include gyroscopes, accelerometers, pressure sensors, infrared sensors, other sensors, timing devices, resonators, tunable capacitors, microphones, microspeakers and the like. For example, a device such as a smart phone, tablet, e-readers, or portable media player may include one or more of a gyroscope, microspeaker, accelerometer or other non-display device. In such a smart phone, tablet, e-reader, portable media player, etc., the non-display electromechanical device can be configured to communicate data to a processor (such as processor 21 of FIG. 29B).

FIGS. 29A and 29B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 29B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43. In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits, algorithm steps, and/or manufacturing processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules, circuits, and/or manufacturing processes described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions or processes described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions or processes may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method comprising:
providing a cover plate including a carrier substrate having a plurality of encapsulation lids attached to the carrier substrate by a removable layer;
aligning the plurality of encapsulation lids with a plurality of devices on a device substrate;
joining the plurality of encapsulation lids to the device substrate; and
exposing the removable layer to a chemical etchant or electromagnetic radiation to thereby release the joined encapsulation lids from the carrier substrate.

2. The method of claim 1, wherein providing the cover plate includes forming recesses in the carrier substrate, conformally coating the carrier substrate including the recesses with the removable layer and forming the encapsulation lids in the coated recesses.

3. The method of claim 1, wherein providing the cover plate includes coating a planar carrier substrate with the removable layer and forming encapsulation lids, each encapsulation lid having a base and sidewalls, on the removable layer.

4. The method of claim 3, further comprising forming bond pad extensions on the carrier substrate, the bond pad extensions having approximately the same thickness as the encapsulation lids.

5. The method of claim 4, wherein at least the sidewalls and the bond pad extensions are formed simultaneously.

6. The method of claim 1, further comprising forming the removable layer by at least one of sputter deposition, electroless plating or evaporation.

7. The method of claim 1, wherein each encapsulation lid includes at least one of nickel (Ni), copper (Cu) or a dielectric material.

8. The method of claim 1, wherein each encapsulation lid includes at least one of nickel (Ni) and a nickel (Ni) alloy.

9. The method of claim 1, wherein the removable layer is a metal layer.

10. The method of claim 9, wherein the removable layer includes at least one of copper (Cu) and aluminum (Al).

11. The method of claim 1, wherein the removable layer includes a laser-cleavable polymer.

12. The method of claim 1, wherein providing the cover plate includes providing the carrier substrate and plating at least part of the encapsulation lids on a seed layer formed on the carrier substrate.

13. The method of claim 12, further comprising sputter depositing the seed layer on the carrier substrate.

14. The method of claim 12, wherein the removable layer is used as the seed layer.

15. The method of claim 1, wherein joining the encapsulation lids to the device substrate includes eutectic or solder bonding.

16. The method of claim 1, wherein the encapsulation lids are joined to the device substrate by a seal of no more than about 200 microns wide.

17. The method of claim 1, wherein the device substrate includes exposed bond pads.

18. The method of claim 1, further comprising dicing the device substrates to form a plurality of individual dies each including an encapsulated electromechanical systems device.

19. The method of claim 1, wherein the devices are electromechanical systems devices.

20. A package fabricated in accordance with the method of claim 1.

21. A method comprising:
forming a removable layer on a carrier substrate by at least one of sputter deposition, electroless plating or evaporation;
forming a plurality of encapsulation lids attached to the carrier substrate by the removable layer;
aligning the plurality of encapsulation lids with a plurality of devices on a device substrate;
joining the plurality of encapsulation lids to the device substrate; and
releasing the joined encapsulation lids from the carrier substrate

22. The method of claim 21, wherein forming a plurality of encapsulation lids includes at least one of electroplating and electroless plating a metal on a seed layer.

23. The method of claim 22, wherein the removable layer is used as the seed layer.

24. The method of claim 21, further comprising forming bond pad extensions on the carrier substrate, the bond pad extensions having approximately the same thickness as the encapsulation lids.

25. The method of claim 21, wherein joining the encapsulation lids to the device substrate includes eutectic or solder bonding.

26. The method of claim 21, wherein releasing the joining encapsulation lids includes exposing the removable layer to at least one of a chemical etchant, electromagnetic radiation and thermal energy.

27. The method of claim 21, wherein the devices are electromechanical systems devices.

28. An apparatus comprising:
a substrate;
an electromechanical systems device disposed on the substrate, wherein the electromechanical systems device has a thickness of at least 3 microns and is covered by an encapsulation lid joined to the substrate; and
one or more exposed contact pads disposed on the substrate outside of the encapsulation lid and electrically connected to the electromechanical systems device.

29. The apparatus of claim 28, wherein the device substrate is glass.

30. The apparatus of claim 28, wherein the encapsulation lid includes Ni or an Ni alloy.

31. The apparatus of claim 28, wherein the encapsulation lid is infrared transparent.

32. The apparatus of claim 28, further comprising a plurality of electromechanical systems devices disposed on the substrate, wherein each of the plurality of electromechanical systems devices has a thickness of at least 3 microns and is individually covered by one of a plurality of encapsulation lids joined to the substrate.

33. The apparatus of claim 28, further comprising:
a display;
a processor that is configured to communicate with the display, the processor being configured to process image data; and
a memory device that is configured to communicate with the processor.

34. The apparatus as recited in claim 33, further comprising:
a driver circuit configured to send at least one signal to the display; and
a controller configured to send at least a portion of the image data to the driver circuit.

35. The apparatus as recited in claim 33, further comprising:
an image source module configured to send the image data to the processor.

36. The apparatus as recited in claim 35, wherein the image source module includes at least one of a receiver, transceiver and transmitter.

37. The apparatus as recited in claim 33, further comprising:
an input device configured to receive input data and to communicate the input data to the processor.

38. The apparatus of claim 33, wherein the electromechanical systems device is the display.

39. The apparatus of claim 33, wherein the electromechanical systems device includes a non-display electromechanical systems device selected from an accelerometer, a gyroscope, and a microspeaker, and the non-display electromechanical systems device is configured to communicate data to the processor.
